(19) United States
(12) Patent Application Publication
(10) Pub. No.: US 2026/0213746 A1
(43) Pub. Date: Jul. 23, 2026

(54) RF SWITCH STRUCTURE DESIGN USING LOCAL BODY BIAS TECHNIQUES FOR REDUCED AREA

(71) Applicant: Qorvo US, Inc., Greensboro, NC (US)

(72) Inventors: Karl J. Couglar, Oak Ridge, NC (US); Ali Tombak, Cary, NC (US); Michael Carroll, Jamestown, NC (US)

(21) Appl. No.: 19/387,049

(22) Filed: Nov. 12, 2025

Related U.S. Application Data
(60) Provisional application No. 63/746,772, filed on Jan. 17, 2025.
(60) Provisional application No. 63/814,803, filed on May 30, 2025.

(51) Int. Cl. H03K 17/687; H01L 23/48; H01L 23/66; H01L 25/065; H10D 80/20

(52) U.S. Cl. CPC H03K 17/687; H10D 80/213; H10D 80/251; H10W 20/20; H10W 44/20; H10W 90/00; H03K 2217/0018; H10W 44/231

(57) ABSTRACT

The present disclosure relates to a radio frequency (RF) switch structure that has a stacked configuration and employs local body bias techniques to achieve a reduced die size and enhanced RF performance. The disclosed RF switch structure includes a bottom wafer providing series-connected bottom field-effect transistors (FETs) and a top wafer over the bottom wafer providing series-connected top FETs, which are electrically parallel to the bottom FETs, respectively. The bottom wafer includes bias resistors configured to provide gate and source-drain direct current (DC) voltage biasing to each of the top and bottom FETs. Additionally, at least one of the top wafer and the bottom wafer includes local body bias circuits, which are configured to provide body DC voltage biasing to each of the top FETs and/or to each of the bottom FETs based on at least the gate DC voltage biasing.

### RELATED APPLICATIONS

This application claims the benefit of provisional patent application Ser. No. 63/746,772, filed Jan. 17, 2025, and provisional patent application Ser. No. 63/814,803, filed May 30, 2025, the disclosures of which are hereby incorporated herein by reference in their entireties.

### FIELD OF THE DISCLOSURE

The present disclosure relates to a radio frequency (RF) switch structure, and in particular to an RF switch structure that has a stacked configuration and employs local body bias techniques to achieve a reduced die size and enhanced RF performance.

### BACKGROUND

There is continuous demand for improvements in device size and performance for radio frequency (RF) products. Smaller die size allows for smaller devices, faster processing speeds, and lower power consumption of RF products. Previously, RF silicon-on-insulator (RFSOI) technology has enabled die size and performance improvement by using more advanced complementary metal oxide semiconductor factories, processes, and tools.

However, reducing the die size of RF products causes several challenges. As the size of the die is reduced, parasitic capacitance and resistance become more prominent because the components are now closer together. This can negatively affect the signal integrity, frequency response, and noise of the RF products. Reduced die size also suffers from less effective thermal management because there is less area for the heat generated by the RF components to be dissipated. Reduced die size requires smaller or tighter tolerances, which require more sophisticated control of the manufacturing processes. These and other impacts of reducing die size alone thus typically increase the complexity and cost of RF products.

An alternative solution to providing more compact and higher performance RF circuits, especially for RF switches, is to utilize a stacked configuration. However, electronic components in a top portion of the stacked configuration will have a larger vertical distance to a silicon handle wafer, such that the thermal performance might be downgraded, and in consequence the reliability of the die might be affected.

Accordingly, there remains a need for improved RF switch structure designs, which utilize the stacked configuration in order to reduce the die size and ensure reliable RF operation. In addition, there is also a need to effectively utilize both top and bottom areas in the stacked configuration.

### SUMMARY

The present disclosure relates to a radio frequency (RF) switch structure that has a stacked configuration and employs local body bias techniques to achieve a reduced die size and enhanced RF performance. The disclosed RF switch structure includes a bottom wafer and a top wafer bonded to and positioned over the bottom wafer. The bottom wafer includes a number of bottom active switch regions, a number of bias resistors, and a number of bottom hybrid bond (HB) vias, while the top wafer includes a number of top active switch regions and a number of top HB vias. Herein, the bottom active switch regions are configured to provide bottom field-effect transistors (FETs), which are electrically coupled in series and surrounded by the bias resistors in a horizontal plane. Each of the bottom HB vias is exposed at a top surface of the bottom wafer and electrically connected to a corresponding one of the bottom FETs. The top active switch regions are formed over the bottom active switch regions, respectively, and configured to provide top FETs that are electrically coupled in series. Each of the top HB vias is exposed at a bottom surface of the top wafer, electrically connected to a corresponding one of the top FETs, and aligned with and directly connected to a corresponding one of the bottom HB vias, such that each of the top FETs is electrically parallel to a corresponding one of the bottom FETs. The bias resistors are configured to provide gate and source-drain direct current (DC) voltage biasing to each of the top FETs and each of the bottom FETs. Additionally, at least one of the top wafer and the bottom wafer further includes a number of local body bias circuits, which are configured to provide body DC voltage biasing to each of the top FETs and/or to each of the bottom FETs based on at least the gate DC voltage biasing.

In one embodiment of the RF switch structure, the local body bias circuits include a number of bottom local body bias circuits and a number of top local body bias circuits. The bottom wafer includes the bottom local body bias circuits, which are configured to provide body DC voltage biasing to each of the bottom FETs based on at least the gate DC voltage biasing. The top wafer includes the top local body bias circuits, which are configured to provide body DC voltage biasing to each of the top FETs based on at least the gate DC voltage biasing.

In one embodiment of the RF switch structure, the bottom local body bias circuits are positioned horizontally outside the bottom active switch regions, while the top local body bias circuits are positioned horizontally outside the top active switch regions.

In one embodiment of the RF switch structure, each of the bottom local body bias circuits is implemented by an integrated diode confined within a corresponding one of the bottom active switch regions. Each of the top local body bias circuits is implemented by an integrated diode confined within a corresponding one of the top active switch regions.

In one embodiment of the RF switch structure, each of the top active switch regions has a same device width as a corresponding one of the bottom active switch regions.

In one embodiment of the RF switch structure, each of the top active switch regions has a greater device width than a corresponding one of the bottom active switch regions, and at least partially covers areas of the bias resistors within the bottom wafer.

In one embodiment of the RF switch structure, the bottom wafer further includes a number of bottom source/drain connection regions and a number of bottom gate connection regions, while the top wafer further includes a number of top source/drain connection regions and a number of top gate connection regions. Herein, each of the bottom source/drain connection regions is connected to a drain or a source of a corresponding one of the bottom FETs, or connected to a drain and a source of two adjacent ones of the bottom FETs, while each of the bottom gate connection regions is connected to a gate of the corresponding one of the bottom FETs. Each of the bottom active switch regions is located between two adjacent ones of the bottom source/drain connection regions in the horizontal plane. Each of the top source/drain connection regions is connected to a drain or a source of a corresponding one of the top FETs, or connected to a drain and a source of two adjacent ones of the top FETs, while each of the top gate connection regions is connected to a gate of the corresponding one of the top FETs. Each of the top active switch regions is located between two adjacent ones of the top source/drain connection regions in the horizontal plane. Each of the bottom HB vias is confined within a corresponding one of the bottom source/drain connection regions or a corresponding one of the bottom gate connection regions, and is electrically connected to a source/drain of the corresponding one of the bottom FETs through the corresponding one of the bottom source/drain connection regions or electrically connected to a gate of the corresponding one of the bottom FETs through the corresponding one of the bottom gate connection regions. Each of the top HB vias is confined within a corresponding one of the top source/drain connection regions or a corresponding one of the top gate connection regions, and is electrically connected to a source/drain of the corresponding one of the top FETs through the corresponding one of the top source/drain connection regions or electrically connected to a gate of the corresponding one of the top FETs through the corresponding one of the top gate connection regions. Additionally, none of the bottom HB vias and the top HB vias are configured to electrically connect bodies of the bottom FETs with bodies of the top FETs.

In one embodiment of the RF switch structure, the bottom source/drain connection regions and the bottom gate connection regions are formed from a same first bottom metal layer, which is at a higher vertical level than the bottom active switch regions. The top source/drain connection regions and the top gate connection regions are formed from a same first top metal layer, which is at a lower vertical level than the top active switch regions.

In one embodiment of the RF switch structure, each of the bottom gate connection regions is horizontally outside a corresponding one of the bottom active switch regions, while each of the top gate connection regions is horizontally outside a corresponding one of the top active switch regions.

In one embodiment of the RF switch structure, each of the bottom gate connection regions is horizontally outside a corresponding one of the bottom active switch regions, while each of the top gate connection regions is horizontally confined in a corresponding one of the top active switch regions.

In one embodiment of the RF switch structure, the local body bias circuits are a number of bottom local body bias circuits, which are included in the bottom wafer. The bottom local body bias circuits are configured to provide body DC voltage biasing to each of the bottom FETs and each of the top FETs based on at least the gate DC voltage biasing.

In one embodiment of the RF switch structure, the local body bias circuits are a number of top local body bias circuits, which are included in the top wafer. The top local body bias circuits are configured to provide body DC voltage biasing to each of the bottom FETs and each of the top FETs based on at least the gate DC voltage biasing.

In one embodiment of the RF switch structure, the bottom wafer further includes a number of bottom source/drain connection regions, a number of bottom gate connection regions, and a number of bottom body connection regions, while the top wafer further includes a number of top source/drain connection regions, a number of top gate connection regions, and a number of top body connection regions. Herein, each of the bottom source/drain connection regions is connected to a drain or a source of a corresponding one of the bottom FETs, or connected to a drain and a source of two adjacent ones of the bottom FETs, each of the bottom gate connection regions is connected to a gate of the corresponding one of the bottom FETs, and each of the bottom body connection regions is connected to a body of the corresponding one of the bottom FETs. Each of the bottom active switch regions is located between two adjacent ones of the bottom source/drain connection regions in the horizontal plane. Each of the top source/drain connection regions is connected to a drain or a source of a corresponding one of the top FETs, or connected to a drain and a source of two adjacent ones of the top FETs, each of the top gate connection regions is connected to a gate of the corresponding one of the top FETs, and each of the top body connection regions is connected to a body of the corresponding one of the top FETs. Each of the top active switch regions is located between two adjacent ones of top source/drain connection regions in the horizontal plane. Each of the bottom HB vias is confined within a corresponding one of the bottom source/drain connection regions, a corresponding one of the bottom gate connection regions, or a corresponding one of the bottom body connection regions, and is electrically connected to a source/drain of the corresponding one of the bottom FETs through the corresponding one of the bottom source/drain connection regions, electrically connected to a gate of the corresponding one of the bottom FETs through the corresponding one of the bottom gate connection regions, or electrically connected to a body of the corresponding one of the bottom FETs through the corresponding one of the bottom body connection regions. Each of the plurality of top HB vias is confined within a corresponding one of the top source/drain connection regions, a corresponding one of the top gate connection regions, or a corresponding one of the top body connection regions, and is electrically connected to a source/drain of the corresponding one of the top FETs through the corresponding one of the top source/drain connection regions, electrically connected to a gate of the corresponding one of the top FETs through the corresponding one of the top gate connection regions, or electrically connected to a body of the corresponding one of the top FETs through the corresponding one of the top body connection regions.

In one embodiment of the RF switch structure, the bottom source/drain connection regions, the bottom gate connection regions, and the bottom body connection regions are formed from a same first bottom metal layer, which is at a higher vertical level than the bottom active switch regions. The top source/drain connection regions, the top gate connection regions, and the top body connection regions are formed from a same first top metal layer, which is at a lower vertical level than the top active switch regions.

In one embodiment of the RF switch structure, each of the bottom gate connection regions and each of the bottom body connection regions are horizontally outside a corresponding one of the bottom active switch regions. Each of the top gate connection regions and each of the top body connection regions are horizontally outside a corresponding one of the top active switch regions.

In one embodiment of the RF switch structure, each of the bottom gate connection regions and each of the bottom body connection regions are horizontally outside a corresponding one of the bottom active switch regions. Each of the top gate connection regions and each of the top body connection regions are horizontally confined in a corresponding one of the top active switch regions.

In one embodiment of the RF switch structure, the body DC voltage biasing provided by the local body bias circuits is solely based on the gate DC voltage biasing.

In one embodiment of the RF switch structure, the body DC voltage biasing provided by the local body bias circuits is partially based on the gate DC voltage biasing.

In one embodiment of the RF switch structure, the bias resistors are placed around the bottom active switch regions along a device width direction. Each of the top active switch regions is positioned over a corresponding one of the bottom active switch regions and extends in the device width direction to at least partially cover the areas of the bias resistors within the bottom wafer, such that each of the top active switch regions has a greater device width than the corresponding one of the bottom active switch regions.

In one embodiment of the RF switch structure, the bias resistors include a number of source-drain bias resistors and a number of gate bias resistors. Each of the source-drain bias resistors is electrically coupled between a drain and a source of a corresponding one of the bottom FETs.

In one embodiment of the RF switch structure, each of the gate bias resistors is coupled between a gate of a corresponding one of the bottom FETs and a gate terminal that provides a gate voltage signal.

In one embodiment of the RF switch structure, the bottom FETs include N bottom FETs, where N is an integer equal to or greater than 2, and the N bottom FETs are coupled in series. The gate bias resistors include N-1 gate bias resistors that are coupled in series between gates of two end FETs of the N bottom FETs, and a common gate bias resistor that is coupled between a gate of one of the N bottom FETs and the gate voltage terminal. A gate of each remaining one of the N bottom FETs other than the two end FETs is coupled to a corresponding joint node of two adjacent ones of the N-1 gate bias resistors.

In one embodiment of the RF switch structure, the common gate bias resistor is coupled between a gate of one end FET of the N bottom FETs and the gate voltage terminal.

In one embodiment of the RF switch structure, the common gate bias resistor is coupled between the gate voltage terminal and a gate of one of the N bottom FETs other than the two end FETs.

In one embodiment of the RF switch structure, the bottom FETs include N+M bottom FETs, where each of N and M is an integer, and the N+M bottom FETs are coupled in series. The gate bias resistors include N+M gate bias resistors. N gate bias resistors are coupled in series between a gate of one end bottom FET of the N+M bottom FETs and the gate voltage terminal, while M gate bias resistors are coupled in series between a gate of another end bottom FET of the M+N bottom FETs and the gate voltage terminal. A gate of each remaining one of the N bottom FETs other than the two end FETs is coupled to a corresponding joint node of two adjacent ones of the N gate bias resistors or a corresponding joint node of two adjacent ones of the M gate bias resistors.

In one embodiment of the RF switch structure, N is equal to M.

In one embodiment of the RF switch structure, N is different from M.

According to one embodiment, a communication device includes receive circuitry, transmit circuitry, and antenna switching circuitry, which is configured to transmit radio frequency signals between antennas and the receive circuitry and/or between the antennas and the transmit circuitry. Herein, the antenna switching circuitry at least includes an RF switch structure, which includes a bottom wafer, and a top wafer bonded to and positioned over the bottom wafer. The bottom wafer includes a number of bottom active switch regions, a number of bias resistors, and a number of bottom hybrid bond (HB) vias, while the top wafer includes a number of top active switch regions and a number of top HB vias. Herein, the bottom active switch regions are configured to provide bottom field-effect transistors (FETs), which are electrically coupled in series and surrounded by the bias resistors in a horizontal plane. Each of the bottom HB vias is exposed at a top surface of the bottom wafer and electrically connected to a corresponding one of the bottom FETs. The top active switch regions are formed over the bottom active switch regions, respectively, and configured to provide top FETs that are electrically coupled in series. Each of the top HB vias is exposed at a bottom surface of the top wafer, electrically connected to a corresponding one of the top FETs, and aligned with and directly connected to a corresponding one of the bottom HB vias, such that each of the top FETs is electrically parallel to a corresponding one of the bottom FETs. The bias resistors are configured to provide gate and source-drain DC voltage biasing to each of the top FETs and each of the bottom FETs. Additionally, at least one of the top wafer and the bottom wafer further includes a number of local body bias circuits, which are configured to provide body DC voltage biasing to each of the top FETs and/or to each of the bottom FETs based on at least the gate DC voltage biasing.

According to one embodiment, a method of implementing an RF switch structure starts with forming a bottom wafer that includes a number of bottom active switch regions, a number of bias resistors, and a number of bottom HB vias. The bottom active switch regions are configured to provide bottom FETs, which are electrically coupled in series and surrounded by the bias resistors in a horizontal plane. Each of the bottom HB vias is exposed at a top surface of the bottom wafer and electrically connected to a corresponding one of the bottom FETs. A top wafer that includes a number of top active switch regions and a number of top HB vias is also formed before, after, or simultaneously with the formation of the bottom wafer. The top active switch regions are configured to provide top FETs that are electrically coupled in series. Each of the top HB vias is exposed at a bottom surface of the top wafer and electrically connected to a corresponding one of the top FETs. At least one of the top wafer and the bottom wafer further includes a number of local body bias circuits. Next, the top wafer is bonded to the bottom wafer. Herein, each of the top HB vias is exposed at the bottom surface of the top wafer and aligned with and directly connected to a corresponding one of the bottom HB vias exposed at the top surface of the bottom wafer, such that each of the top FETs is electrically parallel to a corresponding one of the bottom FETs. The bias resistors are configured to provide gate and source-drain DC voltage biasing to each of the top FETs and each of the bottom FETs. The local body bias circuits are configured to provide body DC voltage biasing to each of the top FETs and/or to each of the bottom FETs based on at least the gate DC voltage biasing.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with

the description serve to explain the principles of the disclosure.

FIGS. 1A and 1B illustrate schematics of a radio frequency (RF) switch structure with a stacked configuration.

FIGS. 2A and 2B illustrate schematics of an RF switch structure with a stacked configuration for better thermal performance.

FIGS. 3A-3D illustrate an implementation of the RF switch structure shown in FIGS. 2A and 2B.

FIGS. 4A-4B illustrate schematics of an exemplary RF switch structure having a stacked configuration and employing local body bias circuitry according to some embodiments of the present disclosure.

FIGS. 5A-5B illustrate an exemplary local body bias circuit according to some embodiments of the present disclosure.

FIGS. 6A-6C illustrate an exemplary implementation of the RF switch structure shown in FIGS. 4A and 4B according to some embodiments of the present disclosure.

FIGS. 7A-7B illustrate an improved implementation of the RF switch structure shown in FIGS. 4A and 4B according to some embodiments of the present disclosure.

FIGS. 8A-8C illustrate an alternative improved implementation of the RF switch structure shown in in FIGS. 4A and 4B according to some embodiments of the present disclosure.

FIGS. 9A and 9B illustrate schematics of an exemplary RF switch structure having a stacked configuration and employing local body bias circuitry only in a bottom switch portion according to some embodiments of the present disclosure.

FIGS. 10A-10B illustrate an exemplary implementation of the RF switch structure shown in FIGS. 9A and 9B according to some embodiments of the present disclosure.

FIGS. 11A-11B illustrate an improved implementation of the RF switch structure shown in FIGS. 9A and 9B according to some embodiments of the present disclosure.

FIGS. 12A and 12B illustrate schematics of an exemplary RF switch structure having a stacked configuration and employing local body bias circuitry only in a top switch portion according to some embodiments of the present disclosure.

FIGS. 13A-13B illustrate an exemplary implementation of the RF switch structure shown in FIGS. 12A and 12B according to some embodiments of the present disclosure.

FIGS. 14A-14B illustrate an improved implementation of the RF switch structure shown in FIGS. 12A and 12B according to some embodiments of the present disclosure.

FIGS. 15A-16B illustrate alternative resistor configurations for gate DC voltage biasing according to some embodiments of the present disclosure.

FIG. 17 illustrates a flowchart of an exemplary implementation process of the RF switch structure according to some embodiments of the present disclosure.

FIG. 18 illustrates a block diagram of an exemplary communication device that includes at least one RF switch structure with the exemplary implementation.

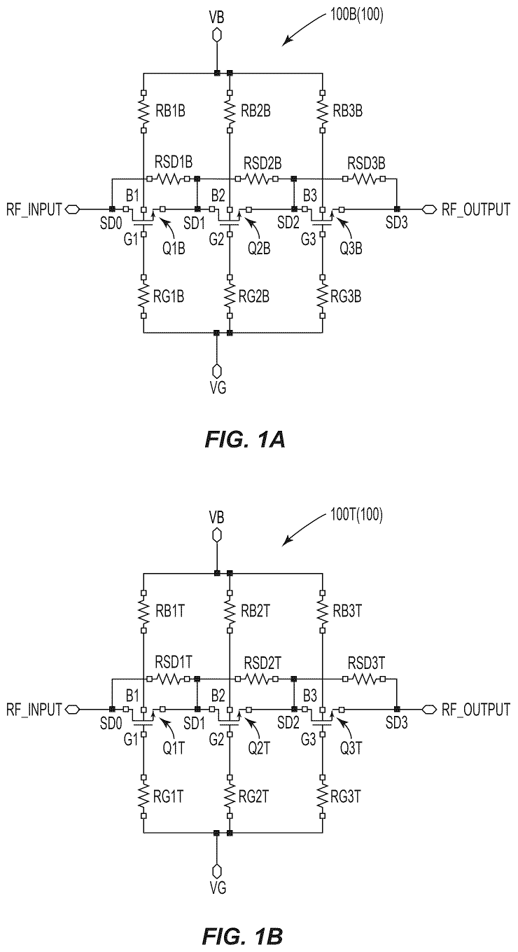

It will be understood that for clear illustrations, FIGS. 1A-18 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

To provide compact and high-performance radio frequency (RF) circuits, a vertically stacked configuration may be utilized in die fabrication. For an RF switch structure, a portion of the RF switch structure can be implemented in a top wafer, while the remaining portion of the RF switch structure can be implemented in a bottom wafer. The top wafer is bonded to and positioned over the bottom wafer, which is formed over a silicon handle wafer (see PCT Patent Application No. PCT/US2023/071309, entitled “WAFER-LEVEL HYBRID BONDED RADIO FREQUENCY CIRCUIT” and PCT Patent Application No. PCT/US2024/057669, entitled “RF SWITCH STRUCTURE DESIGN IN STACKED RFSOI WAFERS FOR REDUCED DIE SIZE,” the disclosures of which are incorporated herein by reference in their entireties). FIGS. 1A and 1B illustrate schematics of a typical RF switch structure 100 with a stacked configuration. FIG. 1A shows a schematic of a bottom switch portion 100B of the RF switch structure 100 intended to be implemented in a bottom wafer, while FIG. 1B shows a schematic of a top switch portion 100T of the RF switch structure 100 intended to be implemented in a top wafer.

To minimize parasitic capacitances associated with the bottom switch portion 100B and the top switch portion 100T, and to avoid metal conductors of significant lengths as part of a fabrication process, the bottom switch portion 100B and the top switch portion 100T are designed to be mirror copies of one another. In this manner, the bottom and top switch portions 100B and 100T are connected in parallel to form the RF switch structure 100.

In detail, RF_INPUT terminals of the bottom switch portion 100B and the top switch portion 100T are connected to one another to form a single RF_INPUT terminal. Similarly, RF_OUTPUT terminals of the bottom switch portion 100B and the top switch portion 100T are connected to one another to form a single RF_OUTPUT terminal. As shown, each of the bottom switch portion 100B and the top switch portion 100T includes a set of bottom field-effect transistors (FETs) QxB (e.g., Q1B, Q2B, and Q3B) and a set of top FETs QxT (e.g., Q1T, Q2T, and Q3T), respectively. The set of the bottom FETs Q1B, Q2B, and Q3B are coupled in series between the RF_INPUT terminal and the RF_OUTPUT terminal. Herein, a drain node of the bottom FET Q1B is coupled to an input node SD0, a source node of the bottom FET Q1B is coupled to a drain node of the bottom FET Q2B at a first node SD1, a source node of the bottom FET Q2B is coupled to a drain node of the bottom FET Q3B at a second node SD2, and a source node of the bottom FET Q3B is coupled to an output node SD3. The input node SD0 is coupled to the RF_INPUT terminal, while the output node SD3 is coupled to the RF_OUTPUT terminal. Similarly, the set of the top FETs Q1T, Q2T, and Q3T are also coupled in series between the RF_INPUT terminal and the RF_OUTPUT terminal, and share the same nodes SD0, SD1, SD2, and SD3 with the set of the bottom FETs Q1B, Q2B, and Q3B. A drain node of the top FET Q1T is coupled to the input node SD0, a source node of the top FET Q1T is coupled to a drain node of the top FET Q2T at the first node SD1, a source node of the top FET Q2T is coupled to a drain node of the top FET Q3T at the second node SD2, and a source node of the top FET Q3T is coupled to the output node SD3. Note that each top/bottom FET QxB/QxT is a bilateral device (e.g., symmetrical device), in which a source and a drain are interchangeable. Each top FET QxT is parallel to a corresponding bottom FET QxB. As such, by fabricating FETs on both top and bottom wafers, a total device width associated with all FETs can be twice that achieved with a non-stacked configuration (i.e., one wafer) in substantially the same footprint.

In order to direct current (DC) bias the RF switch structure 100, each of the bottom switch portion 100B and the top switch portion 100T may also include gate, body, and/or source-drain bias resistors. For a non-limiting example, the bottom switch portion 100B may include three gate bias resistors RG1B, RG2B, and RG3B coupled between a gate voltage terminal VG (e.g., providing a gate voltage signal) and gate terminals G1, G2, and G3 of the bottom FETs Q1B, Q2B, and Q3B, respectively; three body bias resistors RB1B, RB2B, and RB3B coupled between a body voltage terminal VB (e.g., providing a body voltage signal, like ground) and body terminals B1, B2, and B3 of the bottom FETs Q1B, Q2B, and Q3B, respectively; and three source-drain bias resistors RSD1B, RSD2B, and RSD3B coupled between the source node and the drain node of the bottom FETs Q1B, Q2B, and Q3B, respectively. Similarly, gate, body, and source-drain resistors RG1T, RG2T, RG3T, RB1T, RB2T, RB3T, RSD1T, RSD2T, and RSD3T of the top switch portion 100T may be coupled as illustrated and described in the bottom switch portion 100B. Herein, the nodes RF_INPUT, RF_OUTPUT, VG, VB, SD0, SD1, SD2, SD3, G1, G2, G3, B1, B2, and B3 are common (e.g., directly electrically connected) in the bottom switch portion 100B and the top switch portion 100T. In implementations, to ensure that the top wafer and the bottom wafer share these common nodes RF_INPUT, RF_OUTPUT, VG, VB, SD0, SD1, SD2, SD3, G1, G2, G3, B1, B2, and B3, a number of hybrid bond (HB) vias are needed (more details are in the following description).

Under RF operations, the gate, body and source-drain bias resistors within the RF switch structure 100 may have significant current density. However, the gate, body, and source-drain bias resistors RG1T, RG2T, RG3T, RB1T, RB2T, RB3T, RSD1T, RSD2T, and RSD3T of the top switch portion 100T, which are intended to be fabricated in the top wafer, will have larger vertical distances to the silicon handle wafer, potentially resulting in thermal performance degradation. As such, the reliability of the RF switch structure 100 might be affected. It is therefore preferable to keep the gate, body, and source-drain bias resistors of the RF switch structure 100 only in the bottom wafer to enhance the thermal performance, ensure reliable operation, and also optimize bias areas (areas used for bias resistors) for the entire RF switch structure.

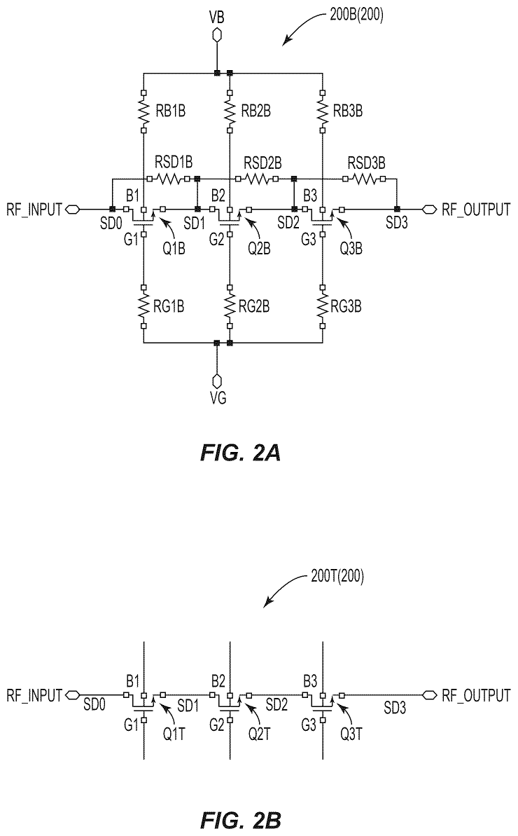

FIGS. 2A and 2B illustrate schematics of an RF switch structure 200 for better thermal performance. FIG. 2A shows a schematic of a bottom switch portion 200B of the RF switch structure 200 intended to be implemented in a bottom wafer, while FIG. 2B shows a schematic of a top switch portion 200T of the RF switch structure 200 intended to be implemented in a top wafer. The bottom switch portion 200B and the top switch portion 200T illustrated in FIGS. 2A and 2B are substantially similar to the bottom switch portion 100B and the top switch portion 100T illustrated in FIGS. 1A and 1B with the exception that the gate, body, and source-drain bias resistors RG1T, RG2T, RG3T, RB1T, RB2T, RB3T, RSD1T, RSD2T, and RSD3T shown in FIG. 1B are omitted in the top switch portion 200T. Since the nodes RF_INPUT, RF_OUTPUT, VG, VB, SD0, SD1, SD2, SD3, G1, G2, G3, B1, B2, and B3 are shared by the set of the bottom FETs Q1B, Q2B, and Q3B and the set of the top FETs Q1T, Q2T, and Q3T, the gate, body, and source-drain bias resistors RG1B, RG2B, RG3B, RB1B, RB2B, RB3B, RSD1B, RSD2B, and RSD3B implemented in the bottom wafer can also be utilized by the set of the top FETs Q1T, Q2T, and Q3T for DC voltage biasing. The resistance values of these bias resistors may be adjusted due to their utilization by both the set of the bottom FETs Q1B, Q2B, and Q3B and the set of the top FETs Q1T, Q2T, and Q3T.

Because the top FETs QxT intended to be implemented in the top wafer will have larger vertical distances to the silicon handle wafer compared to the bottom FETs QxB intended to be implemented in the bottom wafer (the silicon handle wafer is placed underneath the bottom wafer), the top FETs QxT intended to be implemented in the top wafer have a greater thermal resistance in comparison to the bottom FETs QxB intended to be implemented in the bottom wafer. As such, if the top switch portion 200T includes gate, body, and source-drain bias resistors RG1T, RG2T, RG3T, RB1T, RB2T, RB3T, RSD1T, RSD2T, and RSD3T, sizes of these bias resistors in the top wafer are required to be significantly large to ensure good thermal performance. When only the bottom switch portion 200B includes gate, body, and source-drain bias resistors RG1B, RG2B, RG3B, RB1B, RB2B, RB3B, RSD1B, RSD2B, and RSD3B that may have significant current density under RF operations (i.e., absent gate, body, and source-drain bias resistors in the top switch portion 200T), the bias areas consumed in the top wafer can be minimized, and the top switch portion 200T may take advantage of a greater bulk in the top wafer. Accordingly, an asymmetric RF circuit formed by the bottom switch portion 200B and the top switch portion 200T may achieve enhanced thermal performance, increased reliability of operation, and optimized bias area utilization.

In different applications, the top switch portion 200T may include fewer or more top FETs coupled in series between the RF_INPUT terminal and the RF_OUTPUT terminal, and the bottom switch portion 200B correspondingly may include fewer or more bottom FETs coupled in series between the RF_INPUT terminal and the RF_OUTPUT terminal, and fewer or more corresponding bias resistors. Each top FET and its corresponding bottom FET may still be connected and parallel to each other, and utilize the same gate, body, and source-drain bias resistors implemented in the bottom wafer.

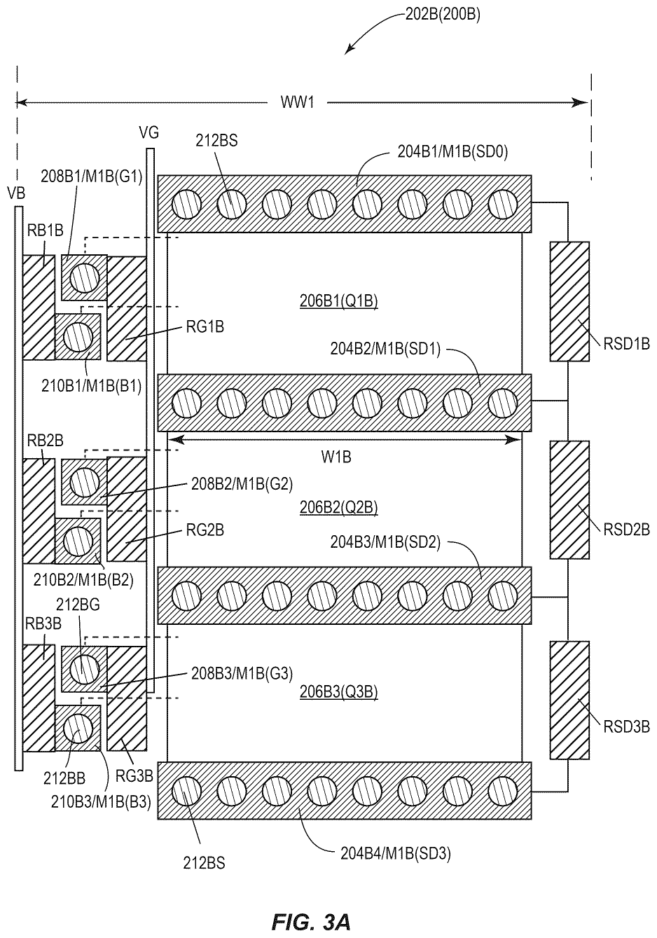

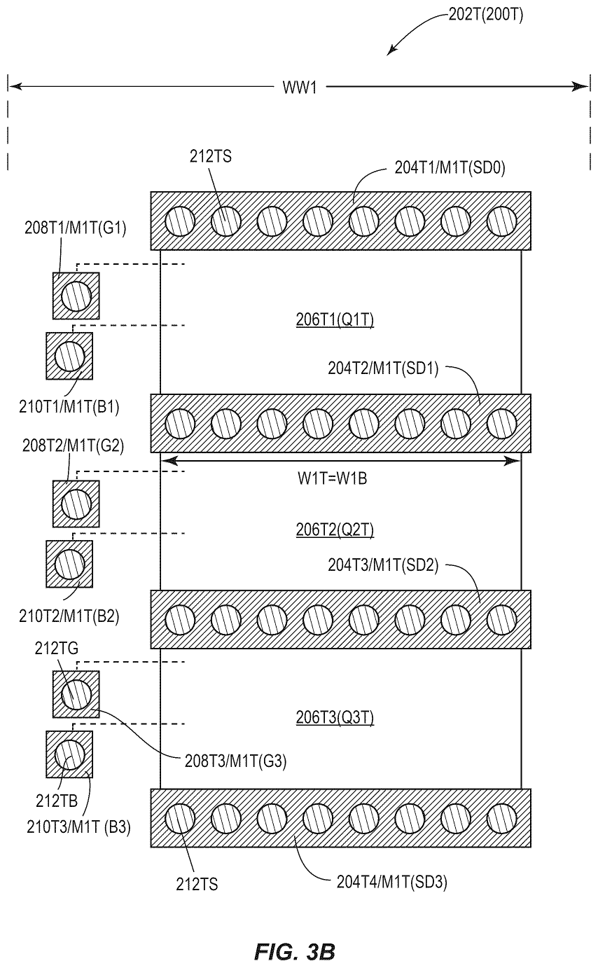

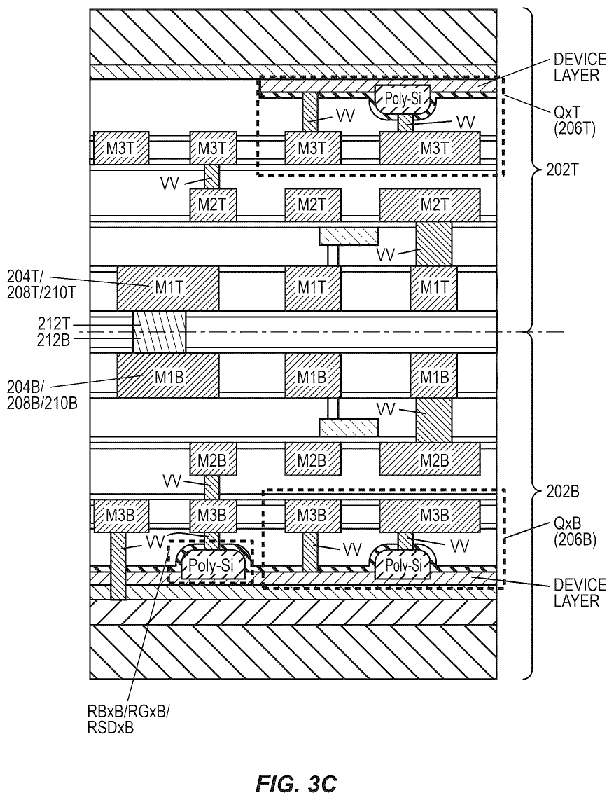

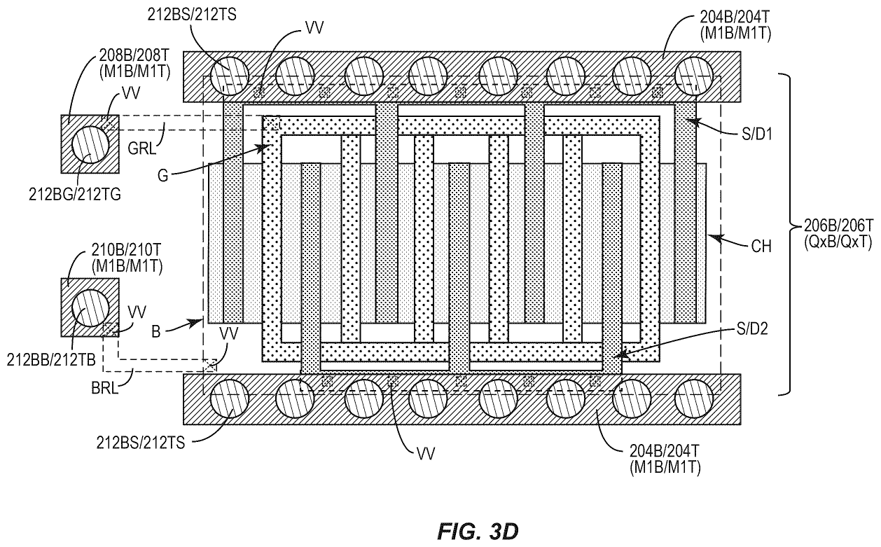

FIGS. 3A and 3B illustrate an implementation 202 of the RF switch structure 200 shown in FIGS. 2A and 2B. FIG. 3A illustrates a top perspective view of a layout of a bottom wafer 202B, within which the bottom switch portion 200B is implemented, and FIG. 3B illustrates a bottom perspective view of a layout of a top wafer 202T, within which the top switch portion 200T is implemented. The top wafer 202T is bonded to and placed over the bottom wafer 202B, such that the set of the top FETs QxT in the top wafer 202T are opposite to the set of the bottom FETs QxB in the bottom wafer 202B, respectively.

Typically, the bottom wafer 202B and the top wafer 202T may each include multiple metal layers and different vertical vias VV between the metal layers to achieve electrical connections, as illustrated in FIG. 3C. Herein, FIG. 3C only shows a small portion of the bottom wafer 202B and a small portion of the top wafer 202T for simplicity. For the purpose of this illustration, the bottom wafer 202B includes a first bottom metal layer M1B as the topmost bottom metal layer, a second bottom metal layer M2B underneath the first bottom metal layer M1B, and a third bottom metal layer M3B underneath the second bottom metal layer M2B, while the top wafer 202T includes a first top metal layer M1T as the bottommost top metal layer, a second top metal layer M2T over the first top metal layer M1T, and a third top metal layer M3T over the second top metal layer M2T. In different applications, the bottom wafer 202B and the top wafer 202T may each include fewer or more metal layers. In addition, the metal layers in the bottom wafer 202B and the top wafer 202T may also constitute certain portions of the bottom FETs QxB and the top FETs QxT, respectively (e.g., source/drain fingers connected to source/drain implants of the FETs QxB QxT, more details are described below).

From horizontal layout aspects (back to FIGS. 3A and 3B), the bottom wafer 202B includes four bottom source/drain connection regions 204B (e.g., a first bottom source/drain connection region 204B1, a second bottom source/drain connection region 204B2, a third bottom source/drain connection region 204B3, and a fourth bottom source/drain connection region 204B4), three bottom active switch regions 206B (e.g., a first bottom active switch region 206B 1, a second bottom active switch region 206B2, and a third bottom active switch region 206B3), three bottom gate connection regions 208B (e.g., a first bottom gate connection region 208B1, a second bottom gate connection region 208B2, and a third bottom gate connection region 208B 3), and three bottom body connection regions 210B (e.g., a first bottom body connection region 210B1, a second bottom body connection region 210B2, and a third bottom body connection region 210B3). Herein, each bottom active switch region 206B is configured to provide a corresponding bottom FET QxB, while the bottom source/drain connection regions 204B, the bottom gate connection regions 208B, and the bottom body connection regions 210B are configured to provide connections from the bottom active switch regions 206B (i.e., from the bottom FETs QxB) towards the top wafer 202T. The bottom source/drain connection regions 204B, the bottom gate connection regions 208B, and the bottom body connection regions 210B are formed from the topmost metal layer (e.g., the first bottom metal layer M1B) in the bottom wafer 202B, which is at a higher vertical level than the bottom active switch regions 206B.

Similarly, the top wafer 202T includes four top source/drain connection regions 204T (e.g., a first top source/drain connection region 204T 1, a second top source/drain connection region 204T2, a third top source/drain connection region 204T3, and a fourth top source/drain connection region 204T4), three top active switch regions 206T (e.g., a first top active switch region 206T1, a second top active switch region 206T2, and a third top active switch region 206T3), three top gate connection regions 208T (e.g., a first top gate connection region 208T1, a second top gate connection region 208T2, and a third top gate connection region 208T3), and three top body connection regions 210T (e.g., a first top body connection region 2 10T1, a second top body connection region 210T2, and a third top body connection region 210T3). Herein, each top active switch region 206T is configured to provide a corresponding top FET QxT, while the top source/drain connection regions 204T, the top gate connection regions 208T, and the top body connection regions 210T are configured to provide connections from the top active switch regions 206T (i.e., from the top FETs QxT) towards the bottom wafer 202B. The top source/drain connection regions 204T, the top gate connection regions 208T, and the top body connection regions 210T are formed from the bottommost metal layer (e.g., the first top metal layer M1T) in the top wafer 202T, which is at a lower vertical level than the top active switch regions 206T.

For a non-limiting example, each FET QxB/QxT in the bottom wafer 202B or in the top wafer 202T might be a multi-finger transistor as illustrated in FIG. 3D. Each bottom/top active switch region 206B/206T substantially indicates a horizontal position where a multi-finger gate G (e.g., an H-shaped gate), a channel CH, a multi-finger drain S/D1 (e.g., a comb structure), a multi-finger source S/D2 (e.g., a comb structure), and a body B of a corresponding FET QxB/QxT are located. The multi-finger gate G, the channel CH, the multi-finger drain S/D1, the multi-finger source S/D2, and the body B of each FET QxB/QxT might be formed at different vertical levels within the bottom/top wafer 202B/202T using metals, polysilicon, dielectrics, or any combination thereof. For instance, the multi-finger drain S/D1 and the multi-finger source S/D2 may be formed from a metal layer in the bottom wafer 202B or in the top wafer 202T (e.g., the second bottom metal layer M2B or the third bottom metal layer M3B in the bottom wafer 202B, the second top metal layer M2T or the third top metal layer M3T in the top wafer 202T, see FIG. 3C) and electrically connected (through vertical vias) to source/drain implants (not shown) in the device layer. The multi-finger gate G may be formed of polysilicon underneath the bottommost bottom metal layer M3B or above the topmost top metal layer M3T. The body B is provided in the device layer underneath the bottommost bottom metal layer M3B or above the topmost top metal layer M3T. Note that each top/bottom FET QxB/QxT is a symmetrical device and therefore the multi-finger drain and source S/D1 and S/D2 of one FET are interchangeable.

In the bottom wafer 202B, the multi-finger gate G, the channel CH, the multi-finger drain S/D1, the multi-finger source S/D2, and the body B of each bottom FET QxB are at lower vertical levels than the topmost bottom metal layer (e.g., the first bottom metal layer M1B). In the top wafer 202T, the multi-finger gate G, the channel CH, the multi-finger drain S/D1, the multi-finger source S/D2, and the body B of each top FET QxT are at higher vertical levels than the bottom most top metal layer (e.g., the first top metal layer M1T).

Each bottom gate connection region 208B may be electrically connected to the multi-finger gate G of the corresponding bottom FET QxB through one or more gate routing lines GRL (e.g., formed from the second bottom metal layer M2B and the third bottom metal layer M3B that are lower than the first bottom metal layer M1B) and one or more vertical vias VV(e.g., vertical vias between the first bottom metal layer M1B and the second bottom metal layer M2B, between the second bottom metal layer M2B and the third bottom metal layer M3B, and between the third bottom metal layer M3B and the multi-finger gate G). Each bottom body connection region 210B may be electrically connected to the body B of the corresponding bottom FET QxB through one or more body routing lines BRL (e.g., formed from the second bottom metal layer M2B and the third bottom metal layer M3B that are lower than the first bottom metal layer M1B) and one or more vertical vias VV (e.g., vertical vias between the first bottom metal layer M1B and the second bottom metal layer M2B, between the second bottom metal layer M2B and the third bottom metal layer M3B, and between the third bottom metal layer M3B and the body B). In this illustration, the bottom gate connection regions 208B and the bottom body connection regions 210B are located horizontally outside the bottom active switch regions 206B. Herein, each bottom gate connection region 208B is connected to the corresponding multi-finger gate G by both the vertical vias VV and the gate routing lines GRL rather than only by vertical vias VV within the corresponding bottom active switch region 206B, so as to avoid unintended short circuits in the bottom active switch regions 206B. Each bottom body connection region 210B is connected to the corresponding body B by both the vertical vias VV and the body routing lines BRL rather than only by vertical vias VV within the corresponding bottom active switch region 206B, so as to avoid unintended short circuits in the bottom active switch regions 206B.

In addition, each bottom source/drain connection region 204B may be electrically connected to a corresponding multi-finger drain and/or a corresponding multi-finger source (e.g., formed from the second bottom metal layer M2B or the third bottom metal layer M3B in the bottom wafer 202B) through multiple vertical vias VV (e.g., vertical vias between the first bottom metal layer M1B and the second bottom metal layer M2B and optionally between the second bottom metal layer M2B and the third bottom metal layer M3B) and optional routing lines (e.g., formed from the second bottom metal layer M2B if the corresponding multi-finger drain S/D is formed from the third bottom metal layer M3B in the bottom wafer 202B). Herein, the second bottom source/drain connection region 204B2 is electrically connected to both the source of the first bottom FET Q1B and the drain of the second bottom FET Q2B, while the third bottom source/drain connection region 204B3 is electrically connected to both the source of the second bottom FET Q2B and the drain of the third bottom FET Q3B. In a horizontal plane, the first bottom active switch region 206B1 is located between the first and second bottom source/drain regions 204B1 and 204B2, the second bottom active switch region 206B2 is located between the second and third bottom source/drain regions 204B2 and 204B 3, and the third bottom active switch region 206B3 is located between the third and fourth bottom source/drain regions 204B3 and 204B4.

Similar concepts apply to the top wafer 202T. Each top gate connection region 208T may be electrically connected to the multi-finger gate G of the corresponding top FET QxT through one or more gate routing lines GRL (e.g., formed from the second top metal layer M2T and the third top metal layer M3T that are located higher than the first top metal layer M1T) and one or more vertical vias VV (e.g., vertical vias between the first top metal layer M1T and the second top metal layer M2T, between the second top metal layer M2T and the third top metal layer M3T, and between the third top metal layer M3T and the multi-finger gate G). Each top body connection region 210T is electrically connected to the body B of the corresponding top FET QxT through one or more body routing lines BRL (e.g., formed from the second top metal layer M2T and the third top metal layer M3T that are located higher than the first top metal layer M1T) and one or more vertical vias VV (e.g., vertical vias between the first top metal layer M1T and the second top metal layer M2T, between the second top metal layer M2T and the third top metal layer M3T, and between the third top metal layer M3T and the body B). In this illustration, the top gate connection regions 208T and the top body connection regions 210T are located horizontally outside the top active switch regions 206T. Herein, each top gate connection region 208T is connected to the corresponding multi-finger gate G by both the vertical vias VV and the gate routing lines GRL rather than only by vertical vias VV within the corresponding top active switch region 206T, so as to avoid unintended short circuits in the top active switch regions 206T. Each top body connection region 210T is connected to the corresponding body B by both the vertical vias VV and the body routing lines BRL rather than only by vertical vias VV within the corresponding top active switch region 206T, so as to avoid unintended short circuits in the top active switch regions 206T.

In addition, each top source/drain connection region 204T may be electrically connected to a corresponding multi-finger drain and/or a corresponding multi-finger source (e.g., formed from the second top metal layer M2T or the third top metal layer M3T in the top wafer 202T) through multiple vertical vias VV (e.g., vertical vias between the first top metal layer M1T and the second top metal layer M2T and optionally between the second top metal layer M2T and the third top metal layer M3T) and optional routing lines (e.g., formed from the second top metal layer M2T if the corresponding multi-finger drain/source is formed from the third top metal layer M3T in the top wafer 202T). Herein, the second top source/drain connection region 2 04T2 is electrically connected to both the source of the first top FET Q1T and the drain of the second top FET Q2T, while the third top source/drain connection region 204T3 is electrically connected to both the source of the second top FET Q2T and the drain of the third top FET Q3T. In the horizontal plane, the first top active switch region 206T1 is located between the first and second top source/drain regions 204T1 and 204T2, the second top active switch region 206T2 is located between the second and third top source/drain regions 204T2 and 204T3, and the third top active switch region 206T3 is located between the third and fourth top source/drain regions 204T3 and 204T4.

Furthermore, the bottom wafer 202B also includes one or more bottom HB vias 212B connected to and confined within the bottom source/drain connection regions 204B, the bottom gate connection regions 208B, and the bottom body connection regions 210B, respectively (e.g., one or more bottom source/drain HB vias 212BS are connected to and confined within each bottom source/drain connection regions 204B, one or more bottom gate HB vias 212BG are connected to and confined within each bottom gate connection regions 208B, and one or more bottom body HB vias 212BB are connected to and confined within each bottom body connection regions 210B, only certain bottom HB vias are labeled with reference numbers for clarity). Each bottom HB via 212B is exposed at a top surface of the bottom wafer 202B. The top wafer 202T includes one or more top HB vias 212T connected to and confined within the top source/drain regions 204T, the top gate connection regions 208T, and the top body connection regions 210T, respectively (e.g., one or more top source/drain HB vias 212TS are connected to and confined within each top source/drain connection regions 204T, one or more top gate HB vias 212TG are connected to and confined within each top gate connection regions 208T, and one or more top body HB vias 212TB are connected to and confined within each top body connection regions 210T, only certain top HB vias are labeled with reference numbers for clarity). Each top HB via 212T is exposed at a bottom surface of the top wafer 202T. The bottom HB vias 212B and the top HB vias 212T are configured to electrically connect the top wafer 202T to the bottom wafer 202B. The bottom HB vias 212B and the top HB vias 212T not only provide electrical connections (e.g., electrical connections at SD0-SD3, G1-G3, and B1-B3) from the bottom wafer 202B to the top wafer 202T but are also important to be included for thermal relief.

For reliable connection/bonding, the top wafer 202T and the bottom wafer 202B are designed, such that once the top wafer 202T is placed over the bottom wafer 202B, each of the top source/drain connection regions 204T, the top active switch regions 206T, the top gate connection regions 208T, and the top body connection regions 210T in the top wafer 202T is aligned over a corresponding one of the bottom source/drain connection regions 204B, the bottom active switch regions 206B, the bottom gate connection regions 208B, and the bottom body connection regions 210B in the bottom wafer 202B. The bottom HB vias 212B in the bottom wafer 202B and the top HB vias 212T in the top wafer 202T are provided in equal numbers and positioned at the same relative locations in the horizontal plane. As such, when the top wafer 202T is mounted on the bottom wafer 202B, each top HB via 212T is vertically aligned with and directly connected to a corresponding bottom HB via 212B.

In detail, the bottom source/drain HB vias 212BS confined within the bottom source/drain regions 204B are directly coupled to the top source/drain HB vias 212TS confined within the top source/drain regions 204T, respectively. As such, the first bottom source/drain region 204B1 and the first top source/drain region 204T1 are connected (i.e., having a same voltage level as the input node SD0 shown in FIGS. 2A and 2B), the second bottom source/drain region 204B2 and the second top source/drain region 2 04T2 are connected (i.e., having a same voltage level as the first node SD1 shown in FIGS. 2A and 2B), the third bottom source/drain region 204B3 and the third top source/drain region 204T3 are connected (i.e., having a same voltage level as the second node SD2 shown in FIGS. 2A and 2B), and the fourth bottom source/drain region 204B4 and the fourth top source/drain region 204 T4 are connected (i.e., having a same voltage level as the output node SD3 shown in FIGS. 2A and 2B). In addition, the bottom gate HB vias 212BG confined within the bottom gate connection regions 208B are directly coupled to the top gate HB vias 212TG confined within the top gate connections region 208T, respectively. As such, the first bottom gate connection region 208B1 and the first top gate connection region 208T1 are connected (i.e., having a same voltage level as the first gate terminals G1 shown in FIGS. 2A and 2B), the second bottom gate connection region 208B2 and the second top gate connection region 208T2 are connected (i.e., having a same voltage level as the first gate terminals G2 shown in FIGS. 2A and 2B), and the third bottom gate connection region 208B3 and the third top gate connection region 208T3 are connected (i.e., having a same voltage level as the third gate terminals G3 shown in FIGS. 2A and 2B). The bottom body HB vias 212BB confined within the bottom body connection regions 210B are directly coupled to the top body HB vias 212TB confined within the top body connection regions 210T, respectively. As such, the first bottom body connection region 210B1 and the first top body connection region 210T1 are connected (i.e., having a same voltage level as the first body terminals B1 shown in FIGS. 2A and 2B), the second bottom body connection region 210B2 and the second top body connection region 210T2 are connected (i.e., having a same voltage level as the first body terminals B2 shown in FIGS. 2A and 2B), and the third bottom body connection region 210B3 and the third top body connection region 210T3 are connected (i.e., having a same voltage level as the third body terminals B3 shown in FIGS. 2A and 2B).

In this illustration, each top FET QxT is electrically parallel to a corresponding bottom FET QxB. If each bottom active switch region 206B has a same device width W1B and each top active switch region 206T has a same device width W1T=W1B, a total device width of FETs in both the top and bottom wafers 202T and 202B (i.e. the RF switch structure 200 with the stacked configuration) will be Wtotal1=W1B+W1T, which might be twice that of which can be achieved by a non-stacked configuration (i.e. one wafer configuration) in substantially the same footprint. By duplicating the top FETs Q1T, Q2T, and Q3T in the top wafer 202T to the bottom FETs Q1B, Q2B, and Q3B in the bottom wafer 202B, the RF switch structure 200 allows a device width of each FET (Q1T/Q2T/Q3T/Q1B/Q2B/Q3B) to be reduced by 30%, 40%, or 50% while maintaining a same overall electrical performance as a conventional RF switch structure with a non-stacked confirmation. For each bottom FET QxB and each top FET QxT, the current density is concentrated at the drain and source. In one embodiment, a width of each bottom source/drain connection region 204B may be substantially equal to the device width W1B of the bottom active switch region 206B, and a width of each top source/drain connection region 204T may be substantially equal to the device width W1T of the top active switch region 206T for good thermal dissipation.

To provide DC voltage biasing to the bottom FETs Q1B, Q2B, and Q3B, the bottom wafer 202B may include the three bottom gate bias resistors RG1B, RG2B, and RG3B, the three bottom body bias resistors RB1B, RB2B, and RB3B, and the three bottom source-drain bias resistors RSD1B, RSD2B, and RSD3B. These bias resistors RG1B, RG2B, RG3B, RB1B, RB2B, RB3B, RSD1B, RSD2B, and RSD3B are typically formed from polysilicon underneath the bottommost bottom metal layer M3B (see FIG. 3C). To avoid shorting the bottom FETs Q1B, Q2B, and Q3B, to ensure a relatively good RF performance, and to achieve a small footprint and a relatively thin profile, the first bottom gate bias resistor RG1B, the first bottom body bias resistor RB1B, and the first bottom source-drain bias resistor RSD1B may be placed to surround the first bottom active switch region 206B1 without overlap in the horizontal plane. The second bottom gate bias resistor RG2B, the second bottom body bias resistor RB2B, and the second bottom source-drain bias resistor RSD2B may surround the second bottom active switch region 206B2 without overlapping in the horizontal plane. The third bottom gate bias resistor RG3B, the third bottom body bias resistor RB3B, and the third bottom source-drain bias resistor RSD3B may surround the third bottom active switch region 206B3 without overlapping in the horizontal plane.

In one embodiment, the first, second, and third bottom gate bias resistors RG1B, RG2B, and RG3B are electrically coupled between the gate voltage terminal VG and the first, second, and third gate terminals G1, G2, and G3, respectively (e.g., between the gate voltage terminal VG and the first, second, and third bottom gate connection regions 208B1, 208B2, and 208B3, respectively) through routing lines (e.g., formed from the second bottom metal layer M2B and/or the third bottom metal layer M3B, not shown) and optionally through vertical vias VV (e.g., vertical vias between the third bottom metal layer M3B and the polysilicon gate bias resistors RGxB, between the second bottom metal layer M2B and the third bottom metal layer M3B, and/or between the first bottom metal layer M1B and the second bottom metal layer M2B, not shown). The first, second, and third bottom body bias resistors RB1B, RB2B, and RB3B may be electrically coupled between the body voltage terminal VB and the first, second, and third body terminals B1, B2, and B3, respectively (e.g., between the body voltage terminal VB and the first, second, and third bottom body connection regions 210B1, 210B2, and 210B3, respectively) through routing lines (e.g., formed from the second bottom metal layer M2B and/or the third bottom metal layer M3B, not shown) and optionally through vertical vias VV (e.g., vertical vias between the third bottom metal layer M3B and the polysilicon body bias resistors RBxB, between the second bottom metal layer M2B and the third bottom metal layer M3B, and/or between the first bottom metal layer M1B and the second bottom metal layer M2B, not shown).

The first source-drain bias resistor RSD1B is electrically coupled between the drain (the input node SD0) of the first bottom FET Q1B and the source (the first node SD1) of the first bottom FET Q1B (i.e., between the first bottom source/drain region 204B1 and the second bottom source/drain region 204B2) through routing lines (e.g., formed from the second bottom metal layer M2B and/or the third bottom metal layer M3B, not shown) and optionally through vertical vias VV (e.g., vertical vias between the third bottom metal layer M3B and the polysilicon first source-drain bias resistor RSD1B, between the second bottom metal layer M2B and the third bottom metal layer M3B, and/or between the first bottom metal layer M1B and the second bottom metal layer M2B, not shown). The second source-drain bias resistor RSD2B is electrically coupled between the drain (the first node SD1) of the second bottom FET Q2B and the source (the second node SD2) of the second bottom FET Q2B (i.e., between the second bottom source/drain region 204B2 and the third bottom source/drain region 204B3) through routing lines (e.g., formed from the second bottom metal layer M2B and/or the third bottom metal layer M3B, not shown) and optionally through vertical vias VV (e.g., vertical vias between the third bottom metal layer M3B and the polysilicon second bottom source/drain region 204B2, between the second bottom metal layer M2B and the third bottom metal layer M3B, and/or between the first bottom metal layer M1B and the second bottom metal layer M2B, not shown). The third source-drain bias resistor RSD3B is electrically coupled between the drain (the second node SD2) of the third bottom FET Q3B and the source (the output node SD3) of the third bottom FET Q3B (i.e., the third bottom source/drain region 204B3 and the fourth bottom source/drain region 204B4) through routing lines (e.g., formed from the second bottom metal layer M2B and/or the third bottom metal layer M3B, not shown) and optionally through vertical vias VV (e.g., vertical vias between the third bottom metal layer M3B and the polysilicon third source-drain bias resistor RSD3B, between the second bottom metal layer M2B and the third bottom metal layer M3B, and/or between the first bottom metal layer M1B and the second bottom metal layer M2B, not shown).

In this illustration, the top HB vias 212T and the bottom HB vias 212B provide connections between the top wafer 202T and the bottom wafer 202B as described above. As such, the DC voltage biasing to the top FETs Q1T, Q2T, and Q3T are also provided through the bottom gate, body, and source-drain bias resistors RG1B, RG2B, RG3B, RB1B, RB2B, RB3B, RSD1B, RSD2B, and RSD3B, which are located on the bottom wafer 202B. As shown and described above, the bottom wafer 202B includes the set of the bottom FETs QxB (with the device width W1B) as well as the gate, body, and source-drain bias resistors RG1B, RG2B, RG3B, RB1B, RB2B, RB3B, RSD1B, RSD2B, and RSD3B surrounding the bottom FETs QxB, while the top wafer 202T includes the set of the top FETs QxT (with the device width W1T) without any gate, body, and source-drain bias resistors. The top wafer 202T may contribute a same amount to the total device width Wtotal1 as the bottom wafer 202B (i.e., W1B=W1T, half of the total device width Wtotal1 would be placed on the bottom wafer 202B and half of the total device width Wtotal1 would be placed on the top wafer 202T) and may have a same footprint as the bottom wafer 202B (i.e., the bottom wafer 202B and the top wafer 202T have a same wafer width WW1).

In some applications, the DC voltage biasing of the body terminals B1, B2, and B3 of the bottom FETs (Q1B, Q2B, and Q3B) and/or the top FETs (Q1T, Q2T, and Q3T) can be achieved locally (e.g., using corresponding gate bias voltages, respectively) without using the body voltage terminal VB and the bottom body bias resistors RB1B, RB2B, and RB3B. By incorporating local body circuits (more details are in the following description) to the bottom wafer 202B and/or the top wafer 202T, the body terminals B1, B2, and B3 of the bottom FETs (Q1B, Q2B, and Q3B) and the top FETs (Q1T, Q2T, and Q3T) can be biased at least in part based on the DC voltage bias voltages at the gate terminals G1, G2, and G3 of the bottom FETs (Q1B, Q2B, and Q3B) and/or the top FETs (Q1T, Q2T, and Q3T).

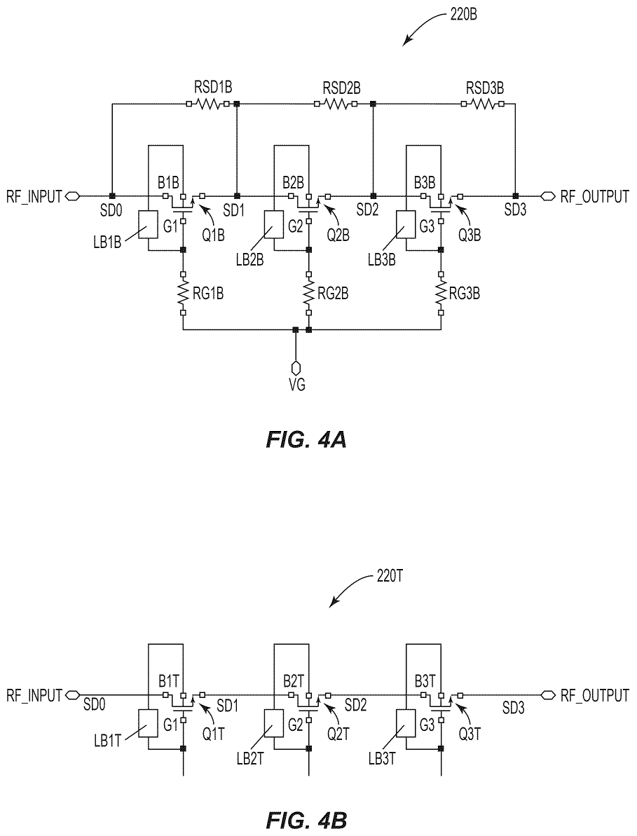

FIGS. 4A and 4B illustrate schematics of an exemplary RF switch structure 220 having a stacked configuration and employing local body bias circuitry according to some embodiments of the present disclosure. FIG. 4A shows a schematic of a bottom switch portion 220B of the RF switch structure 220 intended to be implemented in a bottom wafer, while FIG. 4B shows a schematic of a top switch portion 220T of the RF switch structure 220 intended to be implemented in a top wafer. The bottom switch portion 220B illustrated in FIG. 4A is substantially similar to the bottom switch portion 200B illustrated in FIG. 2A with the exception that the body bias resistors RB1B, RB2B, and RB3B are omitted, and bottom local body bias circuits LB1B, LB2B, and LB3B are introduced. The top switch portion 220T illustrated FIG. 4B is substantially similar to the top switch portion 200T illustrated in FIG. 2B with the exception that top local body bias circuits LB1T, LB2T, and LB3T are introduced. Herein, the nodes RF_INPUT, RF_OUTPUT, VG, SD0, SD1, SD2, SD3, G1, G2, G3, are still shared by the set of the bottom FETs Q1B, Q2B, and Q3B and the set of the top FETs Q1T, Q2T, and Q3T, and the gate and the source-drain bias resistors RG1B, RG2B, RG3B, RSD1B, RSD2B, and RSD3B implemented in the bottom wafer are still utilized by the set of the top FETs Q1T, Q2T, and Q3T for DC voltage biasing.

The bottom local body bias circuits LB1B, LB2B, and LB3B are configured to obtain local gate bias voltages at the gate terminals G1, G2, and G3 of the bottom FETs (Q1B, Q2B, and Q3B), respectively, and to provide body bias voltages to body terminals B1B, B2B, and B3B of the bottom FETs (Q1B, Q2B, and Q3B), respectively. In different applications, each body bias voltage of the bottom FETs (Q1B, Q2B, and Q3B) may be solely or partially based on a corresponding gate bias voltage of the bottom FETs (Q1B, Q2B, and Q3B). Similarly, the top local body bias circuits LB1T, LB2T, and LB3T are configured to obtain local gate bias voltages at the gate terminals G1, G2, and G3 of the top FETs (Q1T, Q2T, and Q3T), and to provide body bias voltages to body terminals B1T, B2T, and B3T of the top FETs (Q1T, Q2T, and Q3T), respectively. Each body bias voltage of the top FETs (Q1T, Q2T, and Q3T) might be solely or partially based on a corresponding gate bias voltage of the top FETs (Q1T, Q2T, and Q3T).

In different applications, the top switch portion 220T may include fewer or more top FETs coupled in series between the RF_INPUT terminal and the RF_OUTPUT terminal, and fewer or more corresponding top local body bias circuits LBxT. The bottom switch portion 220B correspondingly may include fewer or more bottom FETs coupled in series between the RF_INPUT terminal and the RF_OUTPUT terminal, fewer or more corresponding bias resistors, and fewer or more corresponding bottom local body bias circuits LBxB. Each top FET and its corresponding bottom FET may still be connected and parallel to each other, and utilize the same gate and source-drain bias resistors implemented in the bottom wafer.

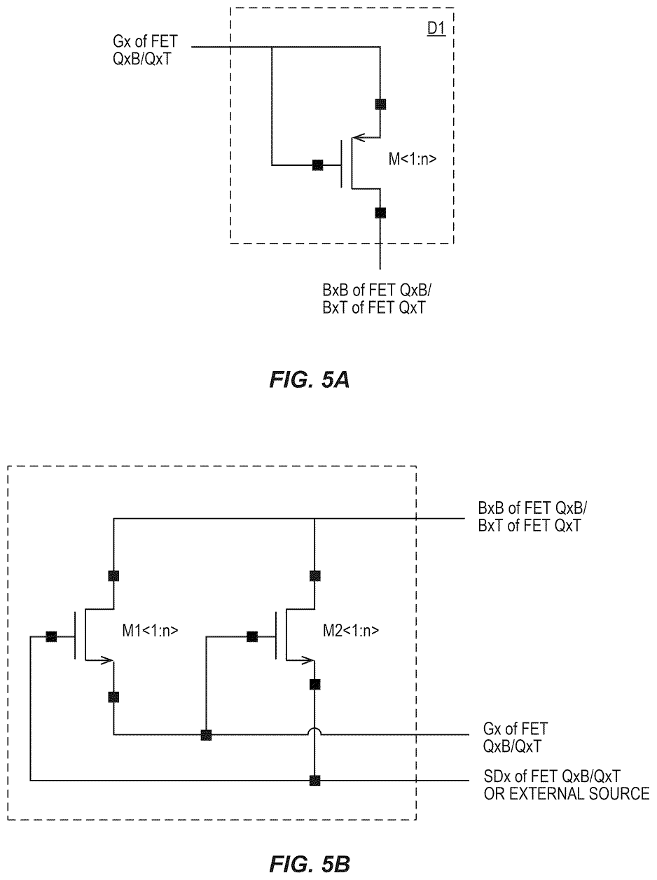

FIGS. 5A and 5B illustrate an exemplary local body bias circuit LBxB/LBxT. In FIG. 5A, the local body bias circuit LBxB/LBxT may include a diode D1, and each body bias voltage of one FET QxB/QxT is solely based on a corresponding gate bias voltage of the same FET QxB/QxT. Herein, the diode D1 may be formed from a P-N junction integrated in a corresponding FET QxB/QxT (not shown) or formed from a source-gate shorted transistor. For a non-limiting example, a P-type transistor (or a set of parallel coupled transistors) M<1:n> is used to form the diode D1, where a source and a gate of the P-type transistor M<1:n> are coupled together and connected to a gate terminal Gx of the bottom/top FET QxB/QxT, while a drain of the P-type transistor M<1:n> is coupled to a body terminal BxB/BxT of the bottom/top FET QxB/QxT.

In FIG. 5B, the local body bias circuit LBxB/LBxT may include two N-type transistors (or two sets of parallel coupled transistors) M<1:n> and M2<1:n>, and each body bias voltage of one FET QxB/QxT is partially based on the corresponding gate bias voltage of the same FET QxB/QxT. In particular, a source of the N-type transistor M1<1:n> and a gate of the N-type transistor M2<1:n> are coupled together and connected to the gate terminal Gx of the bottom/top FET QxB/QxT, and a gate of the N-type transistor M1<1:n> and a source of the N-type transistor M2<1:n> are coupled together and connected to an external source (through a large resistor, not shown here) or a source/drain terminal SDx of the bottom/top FET QxB/QxT. In addition, a drain of the N-type transistor M1<1:n> and a drain of the N-type transistor M1<1:n> are coupled together and connected to a body terminal BxB/BxT of the bottom/top FET QxB/QxT.

Note that since the body terminals B1B, B2B, and B3B of the bottom FETs (Q1B, Q2B, and Q3B) as well as the body terminals B1T, B2T, and B3T of the top FETs (Q1T, Q2T, and Q3T) are locally biased (i.e., the DC voltage biasing is implemented within a corresponding wafer), the top body HB vias 212TB and the bottom body HB vias 212BB are no longer needed to connect the body terminals B1B, B2B, and B3B of the bottom FETs (Q1B, Q2B, and Q3B) and the body terminals B1T, B2T, and B3T of the top FETs (Q1T, Q2T, and Q3T). As such, connection complexity and areas required for the body DC bias interconnect can be reduced, thereby enhancing performance of the entire device. Additionally, although the body terminals B1B, B2B, and B3B of the bottom FETs (Q1B, Q2B, and Q3B) and the body terminals B1T, B2T, and B3T of the top FETs (Q1T, Q2T, and Q3T) are biased separately, they are based on the same common gate bias voltages and can be biased in the same manner. As such, the body bias voltages at the body terminals B1B, B2B, and B3B of the bottom FETs might be substantially the same as those at the body terminals B1T, B2T, and B3T of the top FETs, respectively.

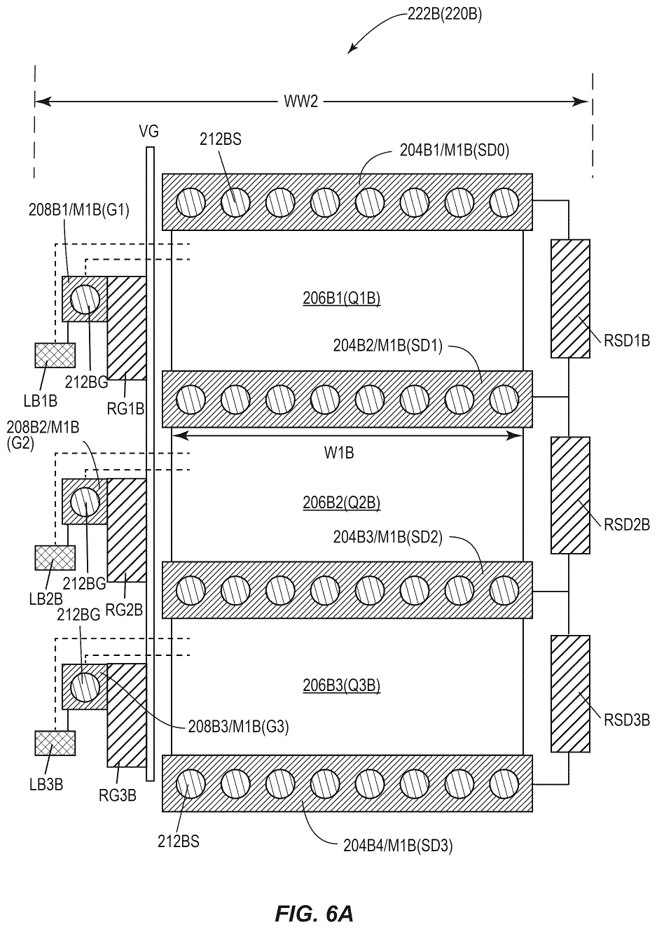

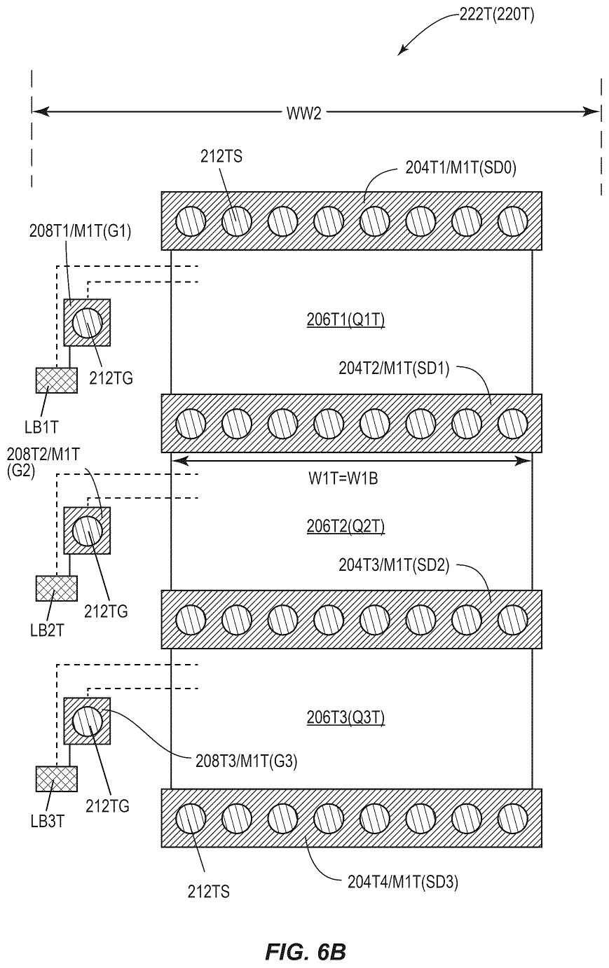

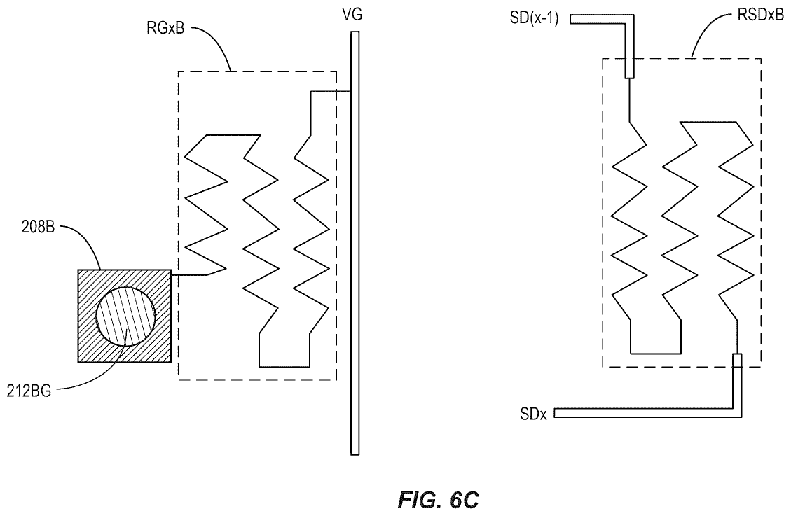

FIGS. 6A-6B illustrate an exemplary implementation 222 of the RF switch structure 220 shown in FIGS. 4A and 4B according to some embodiments of the present disclosure. FIG. 6A illustrates a top perspective view of a layout of a bottom wafer 222B, within which the bottom switch portion 220B is implemented, and FIG. 6B illustrates a bottom perspective view of a layout of a top wafer 222T, within which the top switch portion 220T is implemented. The top wafer 222T is bonded to and placed over the bottom wafer 222B, such that the set of the top FETs QxT in the top wafer 222T are opposite to the set of the bottom FETs QxB in the bottom wafer 222B, respectively.

The bottom wafer 222B and the top wafer 222T may each include multiple metal layers and different vertical vias VV between the metal layers to achieve electrical connections (similar to the bottom wafer 202B and the top wafer 202T shown in FIG. 3C). For a non-limiting example, the bottom wafer 222B also includes the first bottom metal layer M1B as the topmost bottom metal layer, the second bottom metal layer M2B underneath the first bottom metal layer M1B, and the third bottom metal layer M3B underneath the second bottom metal layer M2B, while the top wafer 222T also includes the first top metal layer M1T as the bottommost top metal layer, the second top metal layer M2T over the first top metal layer M1T, and the third top metal layer M3T over the second top metal layer M2T. In different applications, the bottom wafer 222B and the top wafer 222T may each include fewer or more metal layers. In addition, the metal layers in the bottom wafer 222B and the top wafer 222T may also constitute certain portions of the bottom FETs QxB and the top FETs QxT, respectively.

Herein, the bottom wafer 222B illustrated in FIG. 6A is substantially similar to the bottom wafer 202B shown in FIGS. 3A and 3D, with the exception that the body bias resistors RB1B, RB2B, and RB3B and their associated electrical connections (e.g. metal layers and/or vertical vias) to the body voltage terminal VB and to corresponding bodies of the bottom FETs QxB are omitted. The bottom body connection regions 210B and their associated bottom body HB vias 212BB used for body interconnects between the bottom FETs QxB and the top FETs QxT are also omitted. Additionally, depending on different implementations, each bottom local body bias circuit LBxB may be formed external to, fully contained within (not shown), or partially overlapping the corresponding bottom active switch region 206Bx (not shown). For a non-limiting example, when each bottom local body bias circuit LBxB is implemented by an integrated diode (that utilizes a P-N junction within the corresponding bottom active switch region 206Bx), each bottom local body bias circuit LBxB is horizontally constrained within the corresponding bottom active switch region 206Bx. For another non-limiting example, when each bottom local body bias circuits LBxB is implemented by two transistors as shown in FIG. 5B, each bottom local body bias circuit LBxB is positioned outside the bottom active switch regions 206Bx. Moreover, electrical connections (e.g. metal layers and/or vertical vias) are added among the bottom local body bias circuits LB1B, LB2B, and LB3B, the gate terminals G1, G2, and G3 of the bottom FETs QxB, and the bodies of the bottom FETs QxB. Compared to the removed body bias resistors RB1B, RB2B, and RB3B, and the removed bottom body connection regions 210B with the associated bottom body HB vias 212BB, the added bottom local body bias circuits LB1B, LB2B, and LB3B may occupy a relatively smaller footprint. As such, to achieve a same device width W1B for each bottom active switch region 206B, the bottom wafer 222B may have a wafer width WW2 that is no greater than the wafer width WW1 of the bottom wafer 202B.

The top wafer 222T illustrated in FIG. 6B is substantially similar to the top wafer 202T illustrated in FIGS. 3B and 3D, with the exception that the top body connection regions 210T and their associated top body HB vias 212TB used for body interconnects between the top FETs QxT and the bottom FETs QxB are omitted. Additionally, depending on different implementations, each top local body bias circuit LBxT may be formed external to, fully contained within (not shown), or partially overlapping the corresponding top active switch region 206Tx (not shown). For a non-limiting example, when each top local body bias circuit LBxT is implemented by an integrated diode (that utilizes a P-N junction within the corresponding top active switch region 206Tx), each top local body bias circuit LBxT is horizontally constrained within the corresponding top active switch region 206Tx. For another non-limiting example, when each top local body bias circuit LBxT is implemented by two transistors as shown in FIG. 5B, each top local body bias circuit LBxT is positioned outside the top active switch regions 206Tx. Moreover, electrical connections (e.g. metal layers and/or vertical vias) are added among the top local body bias circuits LB1T, LB2T, and LB3T, the gate terminals G1, G2, and G3 of the top FETs QxT, and the bodies of the top FETs QxT. Herein, since the top wafer 222T does not include any bias resistors, when each top active switch region 206T has a width W1T the same as the width W1B of the bottom active switch region 206B in the bottom 222B, the top wafer 222T, with the wafer width WW2, will have sufficient spare space to accommodate the top local body bias circuits LB1T, LB2T, and LB3T. As such, the top and bottom wafers 222T and 222B can provide a same total device width Wtotal 1=W1B+W1T as that of the top wafer 202T and the bottom wafer 202B, while having a smaller footprint/wafer width WW2.

In this embodiment, the nodes RF_INPUT, RF_OUTPUT, VG, SD0, SD1, SD2, SD3, G1, G2, G3, are still shared by the set of the bottom FETs Q1B, Q2B, and Q3B and the set of the top FETs Q1T, Q2T, and Q3T through the corresponding bottom HB vias 212B and top HB vias 212T. The gate and the source-drain bias resistors RG1B, RG2B, RG3B, RSD1B, RSD2B, and RSD3B implemented in the bottom wafer 222B are still utilized by the set of the top FETs Q1T, Q2T, and Q3T for DC voltage biasing. Each bias resistor RGxB/RSDxB (e.g., RG1B, RG2B, RG3B, RSD1B, RSD2B, and RSD3B) may be formed from polysilicon and segmented. Segmented schematics of the bias resistors RGxB and RSDxB are shown in FIG. 6C.

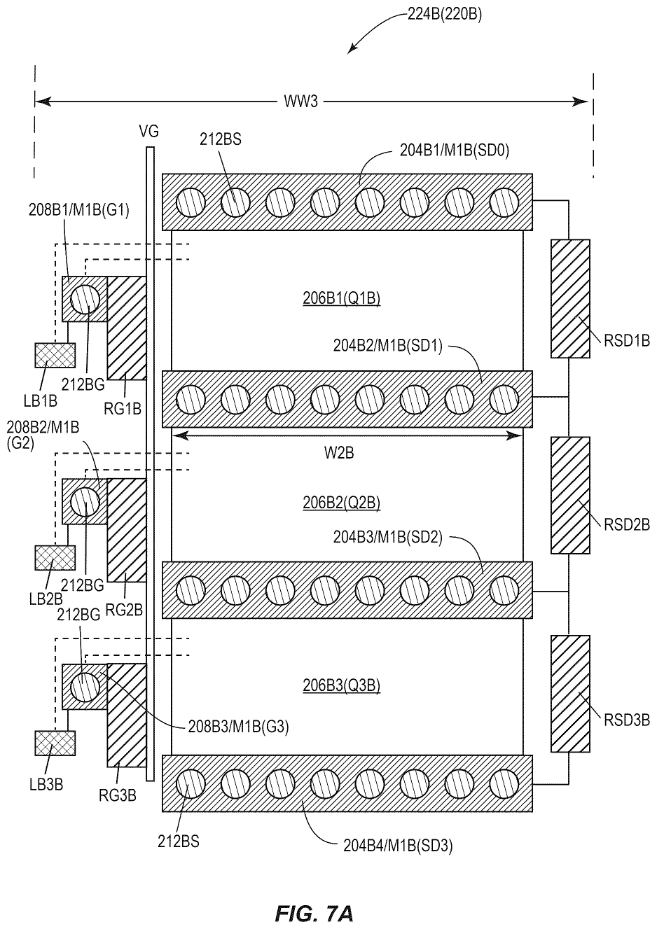

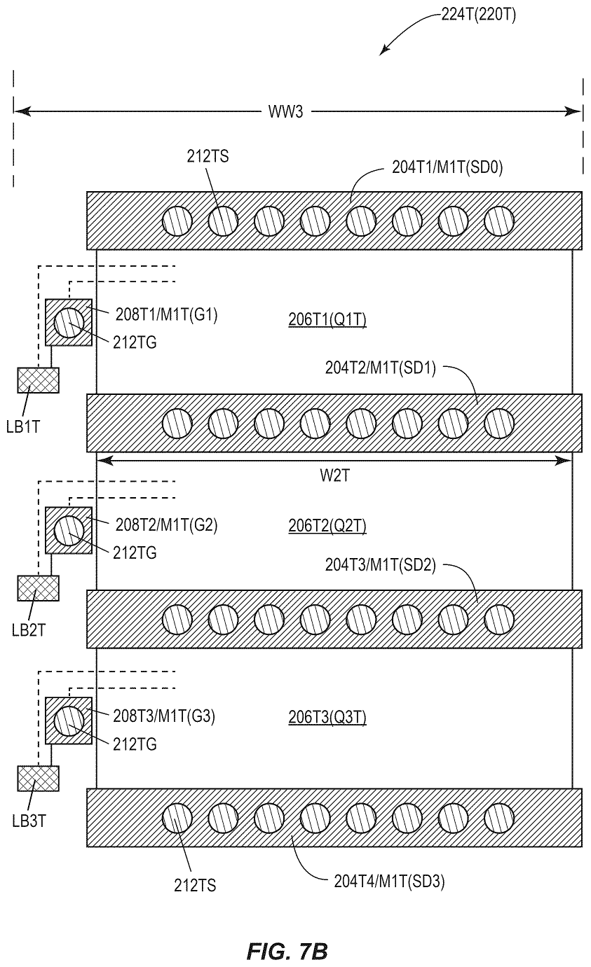

For RF switch applications, which have a relatively small active device width (such as high throw count antenna switches), the area for gate and source-drain bias resistors can be a significant part compared to the area for the active switch regions. Therefore, in the absence of bias resistors, even with the inclusion of the top local body bias circuits LB1T, LB2T, and LB3T, there will still remain unutilized areas around the top FETs QxT in the top wafer 222T, which results in underutilization of the top wafer 222T. FIGS. 7A and 7B illustrate an improved implementation 224 of the RF switch structure 220 according to some embodiments of the present disclosure. FIG. 7A illustrates a top perspective view of a layout of a bottom wafer 224B, within which the bottom switch portion 220B is implemented, and FIG. 7B illustrates a bottom perspective view of a layout of a top wafer 224T, within which the top switch portion 220T is implemented. The top wafer 224T is bonded to and placed over the bottom wafer 224B, such that the set of the top FETs QxT in the top wafer 224T are opposite to the set of the bottom FETs QxB in the bottom wafer 224B, respectively. Each of the bottom wafer 224B and the top wafer 224T may also include multiple metal layers and different vertical vias VV between the metal layers to achieve electrical connections (e.g., similar to the illustration shown in FIG. 3C, the first bottom metal layer M1B, the second bottom metal layer M2B, the third bottom metal layer M3B, the first top metal layer M1T, the second top metal layer M2T, and the third top metal layer M3T).

Herein, the bottom wafer 224B shown in FIG. 7A has a similar layout and configuration as the bottom wafer 222B shown in FIG. 6A, while FET device size reduction can be achieved in the bottom wafer 224B (more details are in the following description). The top wafer 224T shown in FIG. 7B has a similar layout and configuration as the top wafer 222T shown in FIG. 6B, but with improved space utilization. In particular, areas in the top wafer 224T, which are above the gate and source-drain bias resistors RG1B, RG2B, RG3B, RSD1B, RSD2B, and RSD3B of the bottom wafer 224B, can be used to grow the top FETs QxT.

Within the top wafer 224T, each top active switch region 206T extends along the direction of a device width (e.g., along a device width W2T) to at least partially cover the areas of the gate and source-drain bias resistors RG1B, RG2B, RG3B, RSD1B, RSD2B, and RSD3B that surround the corresponding bottom active switch region 206B within the bottom wafer 224B. As such, the device width W2T of each top active switch region 206T is larger than a device width W2B of the corresponding bottom active switch region 206B. Herein, each top gate connection region 208T and the associated top HB via 212TG are still horizontally outside the corresponding top active switch region 206T, while each top local body bias circuit LBxT, depending on different implementations, may be formed external to, fully contained within, or partially overlapping the corresponding top active switch region 206T.

As described above, after the wafer bonding, each top HB via 212T in the top wafer 224T is required to be connected to a corresponding bottom HB via 212B in the bottom wafer 224B. As such, the top HB vias 212T are always provided in the same number and the same relative horizontal locations as the bottom HB vias 212B. However, each top source/drain region 204T may have an extended width greater than a corresponding bottom source/drain region 204B. The extended with of each top source/drain region 204T (e.g., extra usage of the first top metal layer M1T) may help the top HB vias 212T to dissipate heat generated in the top wafer 224T.

In this illustration, each top FET QxT with the device width W2T in the top wafer 224T is electrically parallel to a corresponding bottom FET QxB with the device width W2B in the bottom wafer 224B. A total device width of the FETs in both the top and bottom wafers 224T and 224B will be Wtotal2=W2B+W2T (where W2T>W2B). If the device width W2B of the bottom FETs QxB in the bottom wafer 224B is equal to the device width W1B of the bottom FETs QxB in the bottom wafer 222B, the bottom wafer 224B may have a wafer width WW3 that is substantially the same as the wafer width WW2 of the bottom wafer 222B. On the other hand, the top wafer 224T, having a wafer width WW3 equal to the wafer width WW2 of the top wafer 222T, will have the device width W2T for the top FETs QxT that is greater than the device width W1T of the top FETs QxT in the top wafer 222T. Therefore, with the same footprint/wafer width (WW2=WW3), the total device width Wtotal2 of the FETs in both the top and bottom wafers 224T and 224B will be larger than the total device width Wtotal1 of the FETs in both the top and bottom wafers 222T and 222B. It is because the areas in the top wafer 224T, which are above the gate and source-drain bias resistors RG1B, RG2B, RG3B, RSD1B, RSD2B, and RSD3B of the bottom wafer 224B, may be partially or completely utilized to form the top active switch regions 206T. The increased total device width Wtotal2 of the FETs in both top and bottom wafers 224T and 224B may enhance the overall electrical performance (e.g., reduced turn-on resistance) of the RF switch structure 220.

Alternatively, to maintain the same overall electrical performance (e.g., maintain the same turn-on resistance, where Wtotal2=Wtotal1), the footprint/wafer width WW3 of the implementation 224 can be smaller than the footprint/wafer width WW2 of the implementation 222. An area ratio between the bottom FETs QxB and the bias resistors (the gate and source-drain resistors RG1B, RG2B, RG3B, RSD1B, RSD2B, and RSD3B) will determine the total area/footprint reduction for the implementation 224. The higher that area ratio is, the larger the potential total area/footprint shrink is.

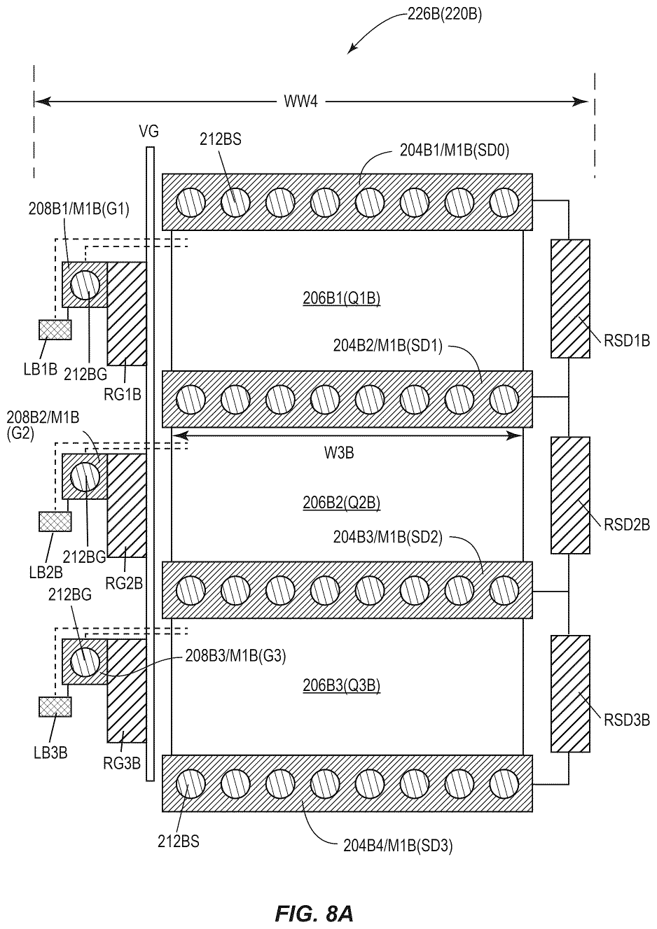

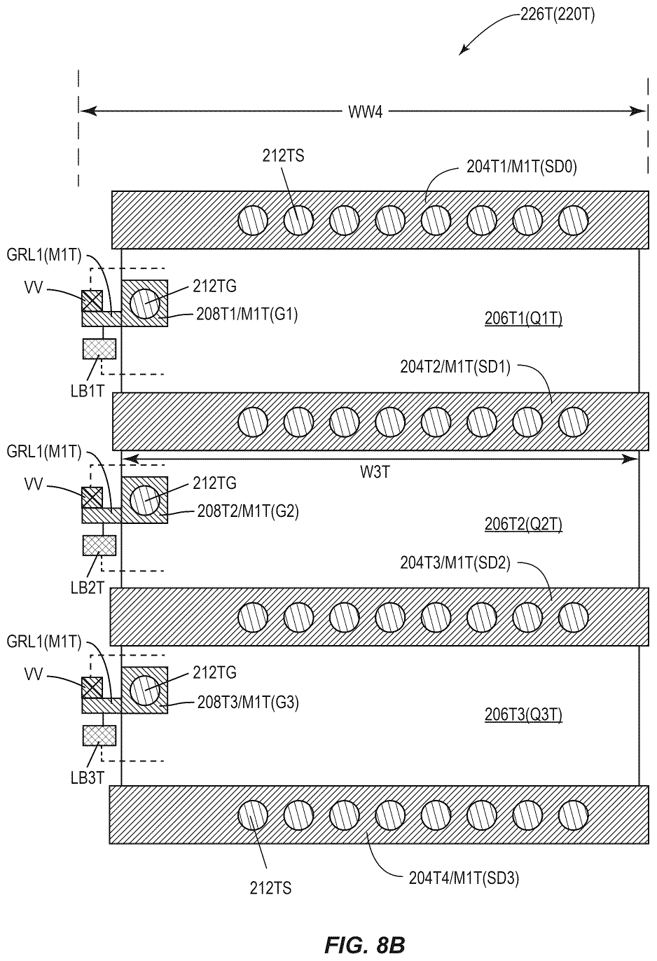

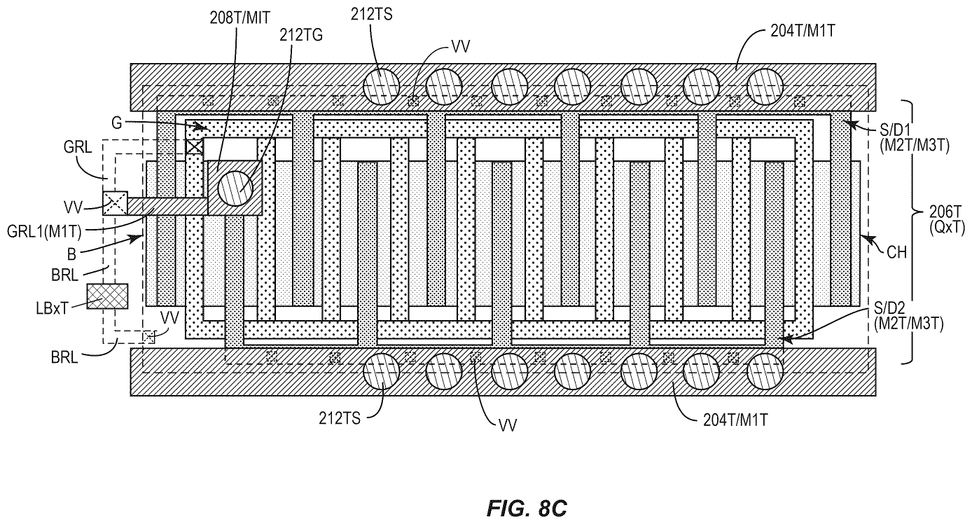

In some embodiments, each top active switch region 206T may further extend along the direction of the device width that each top gate connection region 208T may overlap (e.g., horizontally confined in) a corresponding top active switch region 206T, rather than being located horizontally outside the corresponding top active switch region 206T. FIGS. 8A and 8B illustrate an alternative improved implementation 226 of the RF switch structure 220 according to some embodiments of the present disclosure. FIG. 8A illustrates a top perspective view of a layout of a bottom wafer 226B, within which the bottom switch portion 220B is implemented, and FIG. 8B illustrates a bottom perspective view of a layout of a top wafer 226T, within which the top switch portion 220T is implemented. The top wafer 226T is bonded to and placed over the bottom wafer 226B, such that the set of the top FETs QxT in the top wafer 226T are opposite to the set of the bottom FETs QxB in the bottom wafer 226B, respectively. Each of the bottom wafer 226B and the top wafer 226T may include multiple metal layers and different vertical vias VV between the metal layers to achieve electrical connections (e.g., similar to the illustration shown in FIG. 3C, the first bottom metal layer M1B, the second bottom metal layer M2B, the third bottom metal layer M3B, the first top metal layer M1T, the second top metal layer M2T, and the third top metal layer M3T).

Herein, the bottom wafer 226B shown in FIG. 8A has a similar layout and configuration as the bottom wafer 222B shown in FIG. 6A, while FET device size reduction can be achieved in the bottom wafer 226B (more details are in the following description). The top wafer 226T shown in FIG. 8B has a similar layout and configuration as the top wafer 222T shown in FIG. 6B, but with improved space utilization. Within the top wafer 226T, each top active switch region 206T extends along the direction of a device width (e.g., along a device width W3T) to at least partially cover the areas of the gate and source-drain bias resistors RG1B, RG2B, RG3B, RSD1B, RSD2B, and RSD3B that surround the corresponding bottom active switch region 206B within the bottom wafer 226B. In addition, each top active switch region 206T may extend further (along the direction of the device width) and horizontally overlap with its corresponding top gate connection region 208T (i.e., each top gate connection region 208T is horizontally confined in a corresponding top active switch region 206T). As such, the device width W3T of each top active switch region 206T is larger than a device width W3B of the corresponding bottom active switch region 206B. Herein, each top local body bias circuit LBxT, depending on different implementations, may be formed external to, fully contained within, or partially overlapping the corresponding top active switch region 206T.

If each top FET QxT in the top wafer 226T is a multi-finger transistor, as illustrated in FIG. 8C, each top gate connection region 208T (e.g., formed from the first top metal layer M1T) may overlap the multi-finger drains S/D1 and S/D2 (e.g., formed from the second/third top metal layer M2T/M3T) of the corresponding top active switch region 206T. To electrically connect each top gate connection region 208T to the multi-finger gate G of a corresponding top FET QxT (within the corresponding top active switch region 206T) without shorting circuits, the top wafer 226T may include multiple first gate route lines GRL1 formed from the first top metal layer M1T to provide an electrical connection from the top gate connection region 208T towards a location horizontally outside of the corresponding top active switch region 206T. In addition, the top wafer 226T also includes other gate route lines GRL formed from the second top metal layer M2T and the third top metal layer M3T (located higher than the first top metal layer M1T) and multiple vertical vias VV (e.g., vertical vias between the first gate route lines GRL1 and the other gate route lines GRL, vertical vias between the other gate route lines GRL, vertical vias between the other gate route lines GRL and the multi-finger gate G) to connect each top gate connection region 208T to the multi-finger gate G within the corresponding top active switch region 206T. Herein, if there is no first gate route line GRL1 (formed from the first top metal layer M1T and extending outside the top active switch region 206T) and each top gate connection region 208T is directly connected to the second top metal layer M2T through vertical vias, it may cause short circuits in the top active switch regions 206T. It is because the top gate connection region 208T overlaps the multi-finger drain S/D1 and the multi-finger drain S/D2, which may be formed from the second top metal layer M2T, and thus the vertical vias directly from the top gate connection region 208T to the second top metal layer M2T may accidently cause short circuits of the multi-finger drain S/D1 and the multi-finger drain S/D2. Herein, extra usage of the first top metal layer M1T (e.g., the first gate route lines GRL1 and the extended width of the top source/drain regions 204T) may help the top HB vias 212T to dissipate heat generated in the top wafer 226T.

Furthermore, each top local body bias circuit LBxT depending on different implementations, may be formed external to, fully contained within, or partially overlapping the corresponding top active switch region 206T. When each top local body bias circuit LBxT is positioned outside the corresponding top active switch region 206Tx, each top local body bias circuit LBxT is electrically connected between the body B and the multi-finger gate G (i.e., the top gate connection region 208T) of the corresponding top FET QxT through one or more body routing lines BRL (e.g., formed from the second top metal layer M2T and the third top metal layer M3T that are higher than the first top metal layer M1T) and one or more vertical vias VV (e.g., vertical vias between the first top metal layer M1T and the second top metal layer M2T, between the second top metal layer M2T and the third top metal layer M3T, and between the third top metal layer M3T and the body B). When each top local body bias circuit LBxT is implemented by an integrated diode confined within the corresponding top active switch region 206Tx, each top local body bias circuit LBxT is also electrically connected between the body B and the multi-finger gate G of the corresponding bottom FET QxB through one or more body routing lines BRL and one or more vertical vias VV (not shown).

In this illustration, each top FET QxT with the device width W3T in the top wafer 226T is electrically parallel to a corresponding bottom FET QxB with the device width W3B in the bottom wafer 226B. A total device width of the FETs in both the top and bottom wafers 226T and 226B will be Wtotal3=W3B+W3T (where W3T>W3B). If the device width W3B of the bottom FETs QxB in the bottom wafer 226B is equal to the device width W1B of the bottom FETs QxB in the bottom wafer 222B, the bottom wafer 226B may have a wafer width WW4 that is substantially the same as the wafer width WW2 of the bottom wafer 222B. On the other hand, the top wafer 226T, having a wafer width WW4 equal to the wafer width WW2 of the top wafer 222T, will have the device width W3T for the top FETs QxT that is greater than the device width W1T of the top FETs QxT in the top wafer 222T. Therefore, with the same footprint/wafer width (WW2=WW3=WW4), the total device width Wtotal3 of the FETs in both the top and bottom wafers 226T and 226B will be larger than the total device width Wtotal1 of the FETs in both the top and bottom wafers 222T and 222B (FIGS. 6A and 6B), and even larger than the total device width Wtotal2 of the FETs in both the top and bottom wafers 224T and 224B (FIGS. 7A and 7B). The increased total device width Wtotal3 of the FETs in both top and bottom wafers 226T and 226B may further enhance the overall electrical performance (e.g., reduced turn-on resistance) of the RF switch structure 220.

Alternatively, to maintain the same overall electrical performance (e.g., maintain the same turn-on resistance, where Wtotal3=Wtotal1), the footprint/wafer width WW4 of the implementation 226 can be smaller than the footprint /afer width WW2 of the implementation 222. In a non-limiting example, to achieve the same total device width (Wtotal3=Wtotal1), the device width W3B of the bottom wafer 226B may be reduced by approximately 14% compared to the device width W1B of the bottom wafer 222B, while the device width W3T of the bottom wafer 226T may be increased by approximately 14% compared to the device width W1T of the top wafer 222T. When the gate and source-drain resistors RG1B, RG2B, RG3B, RSD1B, RSD2B, and RSD3B, and the bottom and top local body bias circuits LB1B, LB2B, LB3B, LB1T, LB2T, and LB3T are factored in, the wafer width WW4 of the top/bottom wafer 226T/226B is about 90% of the wafer width WW2 of the top/bottom wafer 222T/222B. An area ratio between the bottom FETs QxB and the bias resistors (the gate and source-drain resistors RG1B, RG2B, RG3B, RSD1B, RSD2B, and RSD3B) will determine the total area/footprint reduction for the implementation 226. The higher that area ratio is, the larger the potential total area/footprint shrink is.

Note that the concepts of improved space utilization in the implementation 224/226 are not limited to the device width reduction. Reductions in device length (orthogonal to the device width) as well as reductions in both the device width and device length are possible, depending on where the gate and source-drain resistors RG1B, RG2B, RG3B, RSD1B, RSD2B, and RSD3B are located in the bottom wafer 224B/226B. When the gate and source-drain resistors RG1B, RG2B, RG3B, RSD1B, RSD2B, and RSD3B reside only along the device width direction of the bottom active switch regions 206B (as illustrated in FIGS. 7A/8A), the reductions can be achieved in the device width. When the gate and source-drain resistors RG1B, RG2B, RG3B, RSD1B, RSD2B, and RSD3B reside only along the length direction of the bottom active switch regions 206B (orthogonal to the device width, not shown), the reductions can be achieved in the device length. When the gate and source-drain resistors RG1B, RG2B, RG3B, RSD1B, RSD2B, and RSD3B reside along both the device width and the length directions of the bottom active switch regions 206B (not shown), the reductions can be achieved in both the device width and the device length.

In some applications, the bodies of the bottom FETs Q1B, Q2B, and Q3B are locally DC biased through the bottom local body bias circuits LB1B, LB2B, and LB3B as described above, while the bodies of the top FETs Q1T, Q2T, and Q3T are also DC biased through the bottom local body bias circuits LB1B, LB2B, and LB3B by being electrically connected to the body terminals B1, B2, and B3 of the bottom FETs Q1B, Q2B, and Q3B, respectively. Herein, the bodies of the top FETs Q1T, Q2T, and Q3T are no longer locally biased.

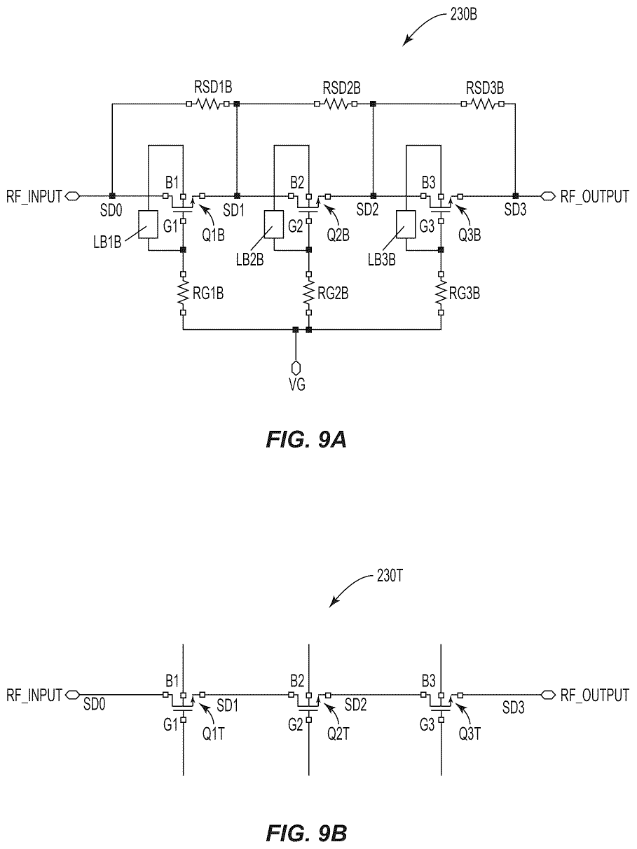

FIGS. 9A and 9B illustrate schematics of an exemplary RF switch structure 230 having a stacked configuration and employing local body bias circuitry only in a bottom switch portion 230B according to some embodiments of the present disclosure. FIG. 9A shows a schematic of the bottom switch portion 230B of the RF switch structure 230 intended to be implemented in a bottom wafer, while FIG. 9B shows a schematic of a top switch portion 230T of the RF switch structure 230 intended to be implemented in a top wafer. The bottom switch portion 230B illustrated in FIG. 9A is substantially similar to the bottom switch portion 220B illustrated in FIG. 4A, with the exception that the bottom switch portion 230B shares common body nodes B1, B2, and B3 with the top switch portion 230T. The top switch portion 230T illustrated FIG. 9B is substantially similar to the top switch portion 220T illustrated in FIG. 4B with the exception that the top local body bias circuits LB1T, LB2T, and LB3T are omitted, and the top switch portion 230T shares common body nodes B1, B2, and B3 with the bottom switch portion 230B. Note that since only the bottom switch portion 230B employs local body biasing, while the top switch portion 230T achieves the body biasing by sharing the common body nodes B1, B2, and B3 with the bottom switch portion 230B, the top body HB vias 212TB and bottom body HB vias 212BB are now required to provide body electrical connections between the bottom FETs Q1B, Q2B, and Q3B and the top FETs Q1T, Q2T, and Q3T, respectively.

In different applications, the top switch portion 230T may include fewer or more top FETs coupled in series between the RF_INPUT terminal and the RF_OUTPUT terminal, while the bottom switch portion 230B correspondingly may include fewer or more bottom FETs coupled in series between the RF_INPUT terminal and the RF_OUTPUT terminal, fewer or more corresponding bias resistors, and fewer or more corresponding bottom local body bias circuits LBxB. Depending on different implementations, each bottom local body bias circuit LBxB may be formed external to, fully contained within, or partially overlapping the corresponding bottom active switch region 206Bx. Each top FET and its corresponding bottom FET may still be connected and parallel to each other, and utilize the same gate and source-drain bias resistors implemented in the bottom wafer.

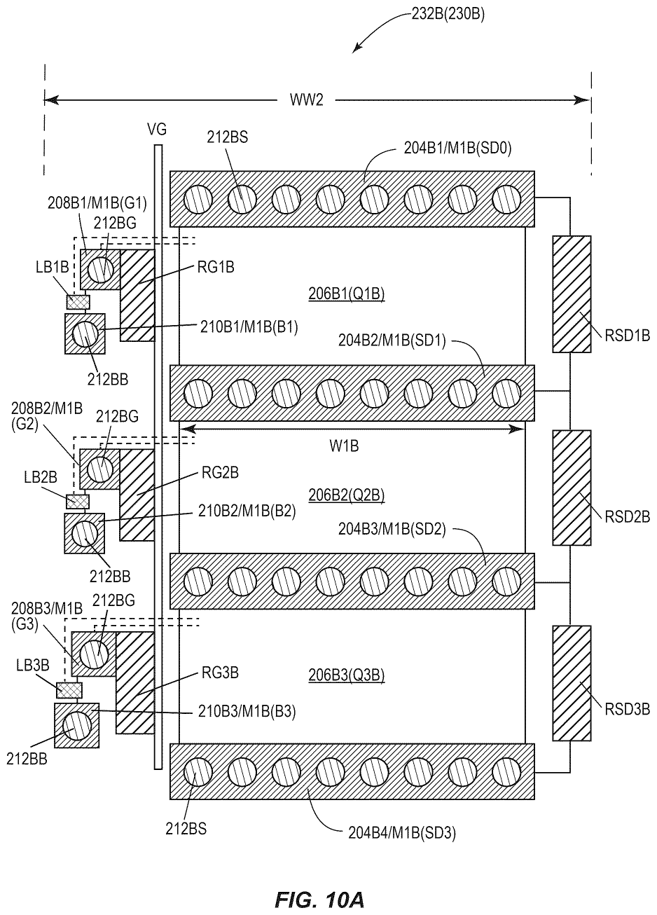

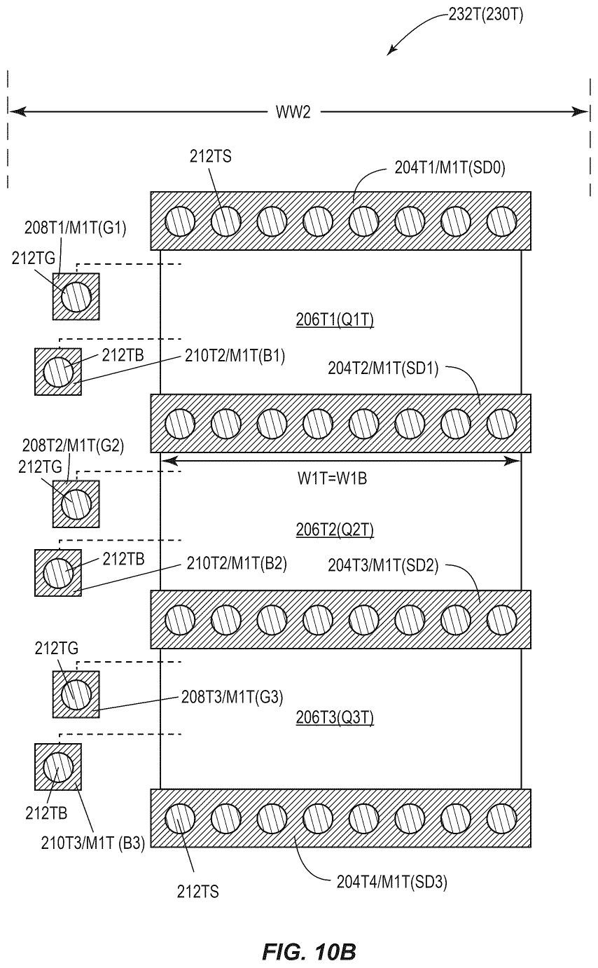

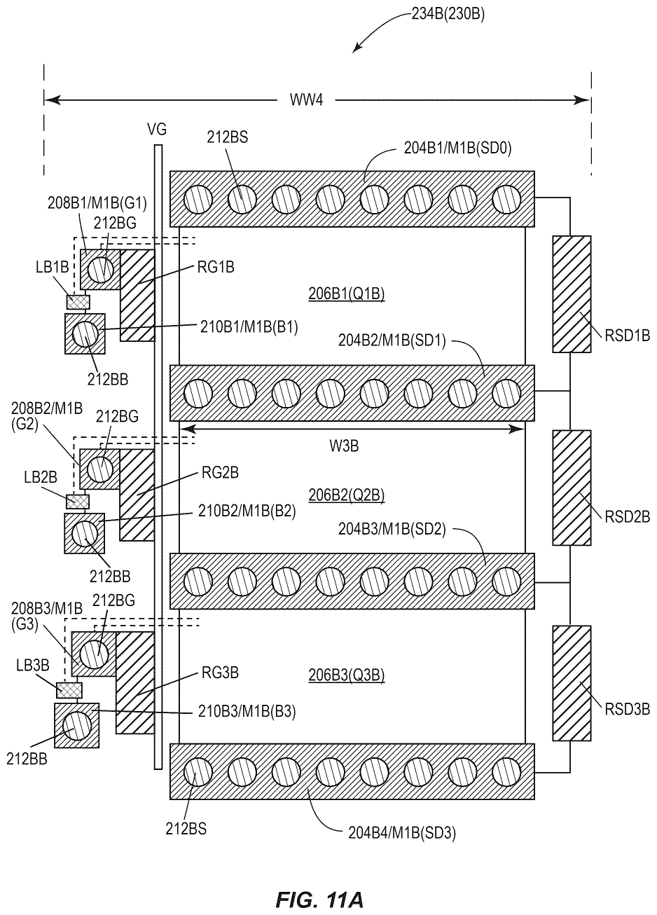

FIGS. 10A-10B illustrate an exemplary implementation 232 of the RF switch structure 230 shown in FIGS. 9A and 9B according to some embodiments of the present disclosure. FIG. 10A illustrates a top perspective view of a layout of a bottom wafer 232B, within which the bottom switch portion 230B is implemented, and FIG. 10B illustrates a bottom perspective view of a layout of a top wafer 232T, within which the top switch portion 230T is implemented. The top wafer 232T is bonded to and placed over the bottom wafer 232B, such that the set of the top FETs QxT in the top wafer 232T are opposite to the set of the bottom FETs QxB in the bottom wafer 232B, respectively.

The bottom wafer 232B and the top wafer 232T may each include multiple metal layers and different vertical vias VV between the metal layers to achieve electrical connections (similar to the bottom wafer 202B and the top wafer 202T shown in FIG. 3C). For a non-limiting example, the bottom wafer 232B also includes the first bottom metal layer M1B as the topmost bottom metal layer, the second bottom metal layer M2B underneath the first bottom metal layer M1B, and the third bottom metal layer M3B underneath the second bottom metal layer M2B, while the top wafer 232T also includes the first top metal layer M1T as the bottommost top metal layer, the second top metal layer M2T over the first top metal layer M1T, and the third top metal layer M3T over the second top metal layer M2T. In different applications, the bottom wafer 232B and the top wafer 232T may each include fewer or more metal layers. In addition, the metal layers in the bottom wafer 232B and the top wafer 232T may also constitute certain portions of the bottom FETs QxB and the top FETs QxT, respectively.

Herein, the bottom wafer 232B illustrated in FIG. 10A is substantially similar to the bottom wafer 222B shown in FIG. 6A, with the exception that the bottom body connection regions 210B (e.g., the first bottom body connection region 2 10B1, the second bottom body connection region 210B2, and the third bottom body connection region 210B3) and their associated bottom body HB vias 212BB used for body interconnects between the bottom FETs QxB and the top FETs QxT are added. Typically, compared to the bottom active switch regions 206B and the bias resistors RG1B, RG2B, RG3B, RSD1B, RSD2B, and RSD3B, the added bottom body connection regions 210B and the associated bottom body HB vias 212BB may occupy a negligibly small footprint. As such, to achieve a same device width W1B for each bottom active switch region 206B, the bottom wafer 232B may have substantially the same wafer width WW2 as the bottom wafer 222B shown in FIG. 6A.

The top wafer 232T illustrated in FIG. 10B is substantially similar to the top wafer 222T illustrated in FIG. 6B, with the exception that the top body connection regions 210T (e.g., the first top body connection region 210T1, the second top body connection region 210T2, and the third top body connection region 210T3) and their associated top body HB vias 212TB used for body interconnects between the top FETs QxT and the bottom FETs QxB are added, while the top local body bias circuits LB1T, LB2T, and LB3T and the associate electrical connections are omitted. Herein, since the top wafer 232T does not include any bias resistors, when each top active switch region 206T still has a device width W1T the same as the device width W1B of the bottom active switch region 206B in the bottom 232B, the top wafer 232T, with the wafer width WW2, will have sufficient spare space to accommodate the top body connection regions 210T and their associated top body HB vias 212TB. As such, the top and bottom wafers 232T and 232B can also provide the same total device width Wtotal1=W1B+W1T as that of the top wafer 222T and the bottom wafer 222B with substantially the same footprint/wafer width WW2.

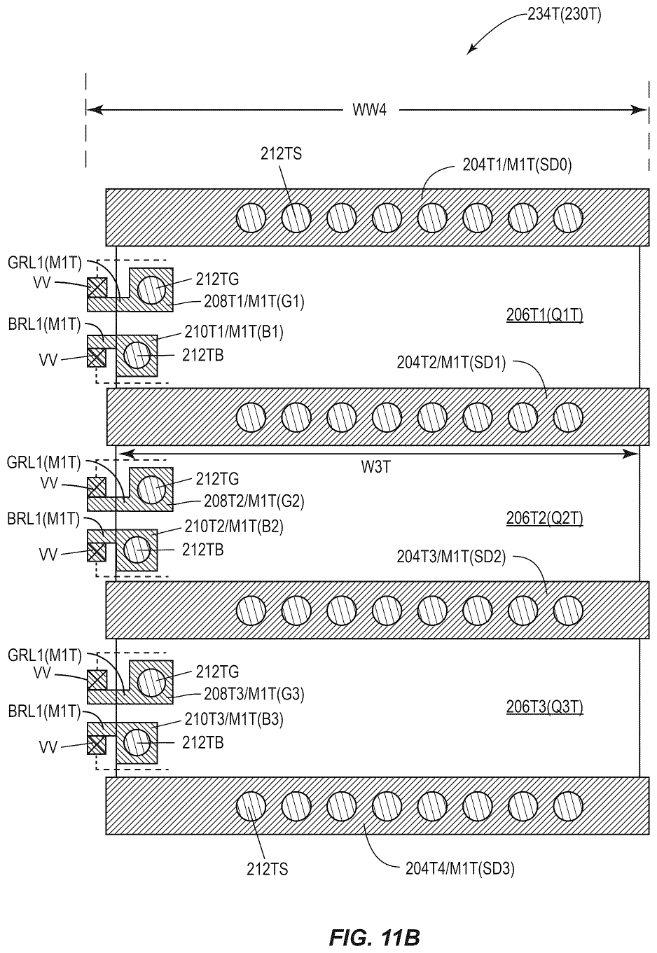

FIGS. 11A and 11B illustrate an improved implementation 234 of the RF switch structure 230 according to some embodiments of the present disclosure. FIG. 11A illustrates a top perspective view of a layout of a bottom wafer 234B, within which the bottom switch portion 230B is implemented, and FIG. 11B illustrates a bottom perspective view of a layout of a top wafer 234T, within which the top switch portion 230T is implemented. The top wafer 234T is bonded to and placed over the bottom wafer 234B, such that the set of the top FETs QxT in the top wafer 234T are opposite to the set of the bottom FETs QxB in the bottom wafer 234B, respectively. Each of the bottom wafer 234B and the top wafer 234T may include multiple metal layers and different vertical vias VV between the metal layers to achieve electrical connections (e.g., similar to the illustration shown in FIG. 3C, the first bottom metal layer M1B, the second bottom metal layer M2B, the third bottom metal layer M3B, the first top metal layer M1T, the second top metal layer M2T, and the third top metal layer M3T).

Herein, the bottom wafer 234B shown in FIG. 11A has a similar layout and configuration as the bottom wafer 232B shown in FIG. 10A, while FET device size reduction can be achieved in the bottom wafer 234B (more details are in the following description). The top wafer 234T shown in FIG. 11B has a similar layout and configuration as the top wafer 232T shown in FIG. 10B, but with improved space utilization. Within the top wafer 234T, each top active switch region 206T extends along the direction of a device width (e.g., along the device width W3T) to at least partially cover the areas of the gate and source-drain bias resistors RG1B, RG2B, RG3B, RSD1B, RSD2B, and RSD3B that surround the corresponding bottom active switch region 206B within the bottom wafer 226B. In addition, each top active switch region 206T may extend further (along the direction of the device width) and horizontally overlap with its corresponding top gate connection region 208T (i.e., each top gate connection region 208T is horizontally confined in a corresponding top active switch region 206T) and corresponding top body connection region 210T (i.e., each top body connection region 210T is horizontally confined in the corresponding top active switch region 206T). As such, the device width W3T of each top active switch region 206T is larger than the device width W3B of the corresponding bottom active switch region 206B.

In some applications, each top active switch region 206T extends along the direction of the device width to at least partially cover the areas of the gate and source-drain bias resistors RG1B, RG2B, RG3B, RSD1B, RSD2B, and RSD3B that surround the corresponding bottom active switch region 206B within the bottom wafer 234B, but without overlapping with its corresponding top gate connection region 208T or top body connection region 210T (not shown). Still, each top active switch region 206T has a larger device width than that of the corresponding bottom active switch region 206B.

If each top active switch region 206T overlaps its corresponding top gate connection region 208T/top body connection region 210T, extra route lines may be needed for electrical connections within the top wafer 234T. As described above (for the top wafer 226T), to electrically connect each top gate connection region 208T to a gate Gx of a corresponding top FET QxT (within the corresponding top active switch region 206T) without shorting circuits, the top wafer 234T may include multiple first gate route lines GRL1 formed from the first top metal layer M1T to provide an electrical connection from the top gate connection region 208T towards a location horizontally outside of the corresponding top active switch region 206T. In addition, the top wafer 234T also includes other gate route lines formed from the second top metal layer M2T and the third top metal layer M3T (located higher than the first top metal layer M1T) and multiple vertical vias VV (e.g., vertical vias between the first gate route lines GRL1 and the other gate route lines, vertical vias between the other gate route lines, and vertical vias between the other gate route lines and the gate Gx) to connect each top gate connection region 208T to the gate Gx within the corresponding top active switch region 206T.

Similarly, to electrically connect each top body connection region 210T to a body Bx of a corresponding top FET QxT (within the corresponding top active switch region 206T) without shorting circuits, the top wafer 234T may include multiple first body route lines BRL1 formed from the first top metal layer M1T to provide an electrical connection from the top body connection region 210T towards a location horizontally outside of the corresponding top active switch region 206T. In addition, the top wafer 234T also includes other body route lines formed from the second top metal layer M2T and the third top metal layer M3T (located higher than the first top metal layer M1T) and multiple vertical vias VV (e.g., vertical vias between the first body route lines BRL1 and the other body route lines, vertical vias between the other body route lines, and vertical vias between the other body route lines and the body Bx) to connect each top body connection region 210T to the body Bx within the corresponding top active switch region 210T. Herein, extra usage of the first top metal layer M1T (e.g., the first gate route lines GRL1, the first body route lines BRL1, and the extended width of the top source/drain regions 204T) may help the top HB vias 212T to dissipate heat generated in the top wafer 234T.

In this illustration, each top FET QxT with the device width W3T in the top wafer 234T is electrically parallel to a corresponding bottom FET QxB with the device width W3B in the bottom wafer 234B. A total device width of the FETs in both the top and bottom wafers 234T and 234B will be Wtotal3=W3B+W3T (where W3T>W1B). If the device width W3B of the bottom FETs QxB in the bottom wafer 234B is equal to the device width W1B of the bottom FETs QxB in the bottom wafer 222B, the bottom wafer 234B may have a wafer width WW4 that is substantially the same as the wafer width WW2 of the bottom wafer 222B. On the other hand, the top wafer 234T, having a wafer width WW4 equal to the wafer width WW2 of the top wafer 222T, will have the device width W3T for the top FETs QxT that is greater than the device width W1T of the top FETs QxT in the top wafer 222T. Therefore, with the same footprint/wafer width (WW2=WW4), the total device width Wtotal3 of the FETs in both top and bottom wafers 234T and 234B will be larger than the total device width Wtotal1 of the FETs in both top and bottom wafers 232T and 232B (FIGS. 10A and 10B). The increased total device width Wtotal3 of the FETs in both top and bottom wafers 234T and 234B may further enhance the overall electrical performance (e.g., reduced turn-on resistance) of the RF switch structure 230.

Alternatively, to maintain the same overall electrical performance (e.g., maintain the same turn-on resistance, where Wtotal3=Wtotal1), the footprint/wafer width WW4 of the implementation 234 can be smaller than the footprint/wafer width WW2 of the implementation 232. In a non-limiting example, to achieve the same total device width (Wtotal3=Wtotal1), the device width W3B of the bottom wafer 234B may be reduced by approximately 14% compared to the device width W1B of the bottom wafer 232B, while the device width W3T of the bottom wafer 234T may be increased by approximately 14% compared to the device width W1T of the top wafer 232T. When the gate and source-drain resistors RG1B, RG2B, RG3B, RSD1B, RSD2B, and RSD3B, and the bottom local body bias circuits LB1B, LB2B, and LB3B are factored in, the wafer width WW4 of the top/bottom wafer 234T/234B is about 90% of the wafer width WW2 of the top/bottom wafer 232T/232B. An area ratio between the bottom FETs QxB and the bias resistors (the gate and source-drain resistors RG1B, RG2B, RG3B, RSD1B, RSD2B, and RSD3B) will determine the total area/footprint reduction for the implementation 234. The higher that area ratio is, the larger the potential total area/footprint shrink is.

In some applications, the bodies of the top FETs Q1T, Q2T, and Q3T are locally DC biased through the top local body bias circuits LB1T, LB2T, and LB3T as described above, while the bodies of the bottom FETs Q1B, Q2B, and Q3B are also DC biased through the top local body bias circuits LB1T, LB2T, and LB3T by being electrically connected to the body terminals B1, B2, and B3 of the top FETs Q1T, Q2T, and Q3T, respectively. Herein, the bodies of the bottom FETs Q1B, Q2B, and Q3B are no longer locally biased.

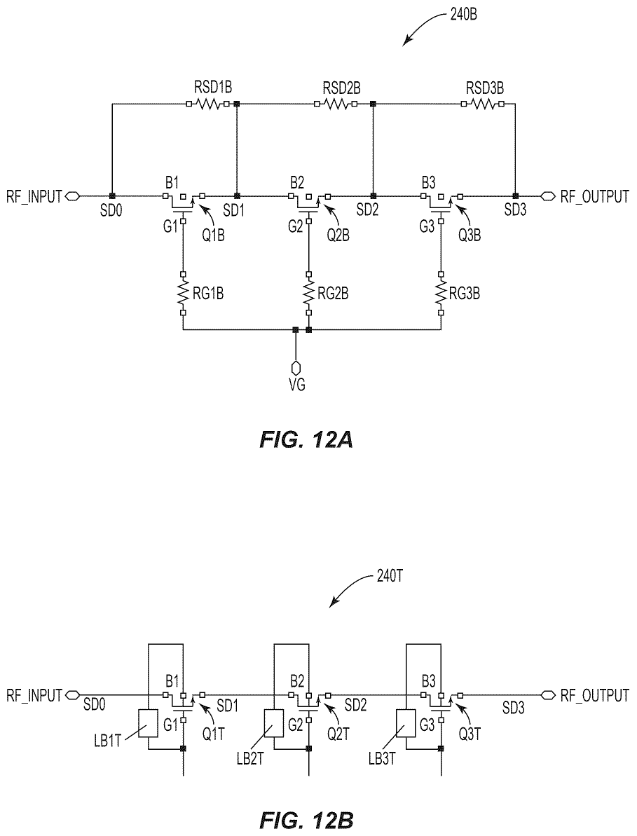

FIGS. 12A and 12B illustrate schematics of an exemplary RF switch structure 240 having a stacked configuration and employing local body bias circuitry only in a top switch portion 240T according to some embodiments of the present disclosure. FIG. 12A shows a schematic of the bottom switch portion 240B of the RF switch structure 240 intended to be implemented in a bottom wafer, while FIG. 12B shows a schematic of a top switch portion 240T of the RF switch structure 240 intended to be implemented in a top wafer. The bottom switch portion 240B illustrated in FIG. 12A is substantially similar to the bottom switch portion 220B illustrated in FIG. 4A, with the exception that the bottom local body bias circuits LB1B, LB2B, and LB3B are omitted, and the bottom switch portion 240B shares common body nodes B1, B2, and B3 with the top switch portion 240T. The top switch portion 240T illustrated FIG. 12B is substantially similar to the top switch portion 220T illustrated in FIG. 4B with the exception that the top switch portion 240T shares the common body nodes B1, B2, and B3 with the bottom switch portion 240B. Note that since only the top switch portion 240T employs local body biasing, while the bottom switch portion 240B achieves the body biasing by sharing the common body nodes B1, B2, and B3 with the top switch portion 240T, the bottom body HB vias 212BB and the top body HB vias 212TB are required to provide body electrical connections between the bottom FETs Q1B, Q2B, and Q3B and the top FETs Q1T, Q2T, and Q3T, respectively.

In different applications, the top switch portion 240T may include fewer or more top FETs coupled in series between the RF_INPUT terminal and the RF_OUTPUT terminal, and fewer or more corresponding top local body bias circuits LBxT. Depending on different implementations, each top local body bias circuit LBxT may be formed external to, fully contained within, or partially overlapping the corresponding bottom active switch region 206Tx. The bottom switch portion 240B correspondingly may include fewer or more bottom FETs coupled in series between the RF_INPUT terminal and the RF_OUTPUT terminal, and fewer or more corresponding bias resistors. Each top FET and its corresponding bottom FET may still be connected and parallel to each other, and utilize the same gate and source-drain bias resistors implemented in the bottom wafer.

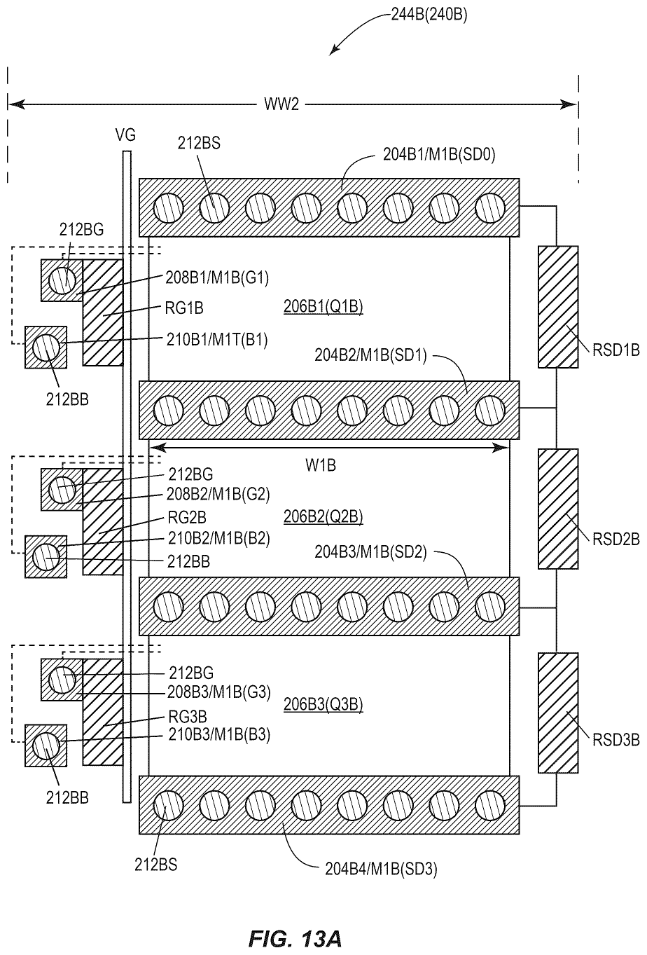

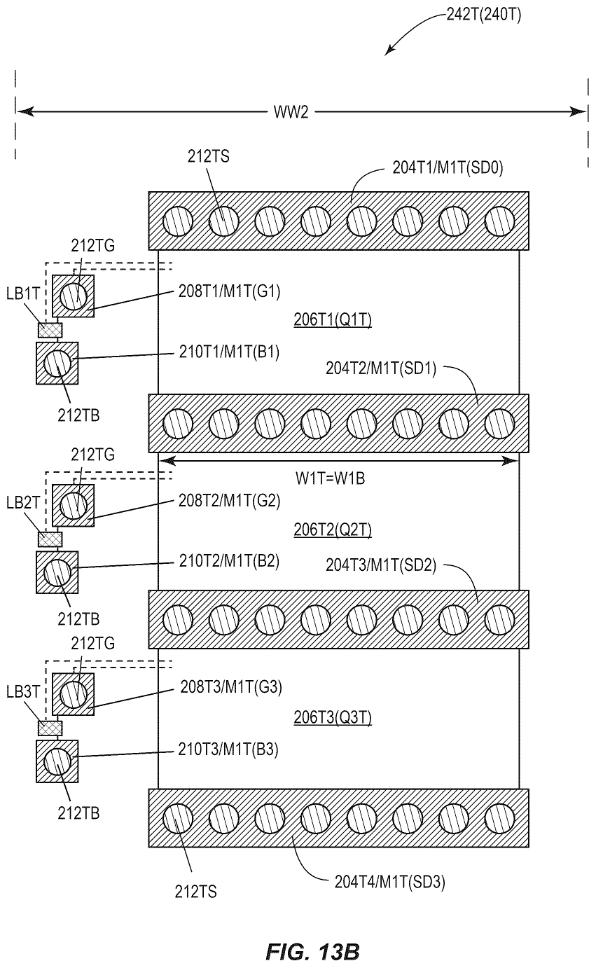

FIGS. 13A-13B illustrate an exemplary implementation 242 of the RF switch structure 240 shown in FIGS. 12A and 12B according to some embodiments of the present disclosure. FIG. 13A illustrates a top perspective view of a layout of a bottom wafer 242B, within which the bottom switch portion 240B is implemented, and FIG. 13B illustrates a bottom perspective view of a layout of a top wafer 242T, within which the top switch portion 240T is implemented. The top wafer 242T is bonded to and placed over the bottom wafer 242B, such that the set of the top FETs QxT in the top wafer 242T are opposite to the set of the bottom FETs QxB in the bottom wafer 242B, respectively.

The bottom wafer 242B and the top wafer 242T may each include multiple metal layers and different vertical vias VV between the metal layers to achieve electrical connections (similar to the bottom wafer 202B and the top wafer 202T shown in FIG. 3C). For a non-limiting example, the bottom wafer 242B also includes the first bottom metal layer M1B as the topmost bottom metal layer, the second bottom metal layer M2B underneath the first bottom metal layer M1B, and the third bottom metal layer M3B underneath the second bottom metal layer M2B, while the top wafer 242T also includes the first top metal layer M1T as the bottommost top metal layer, the second top metal layer M2T over the first top metal layer M1T, and the third top metal layer M3T over the second top metal layer M2T. In different applications, the bottom wafer 242B and the top wafer 242T may each include fewer or more metal layers. In addition, the metal layers in the bottom wafer 242B and the top wafer 242T may also constitute certain portions of the bottom FETs QxB and the top FETs QxT, respectively.

Herein, the bottom wafer 242B illustrated in FIG. 13A is substantially similar to the bottom wafer 222B shown in FIG. 6A, with the exception that the bottom body connection regions 210B (e.g., the first bottom body connection region 210B1, the second bottom body connection region 210B2, and the third bottom body connection region 210B3) and their associated bottom body HB vias 212BB used for body interconnects between the bottom FETs QxB and the top FETs QxT are added, while the bottom local body bias circuits LB1B, LB2B, and LB3B and the associated electrical connections are omitted. Typically, compared to the bottom active switch regions 206B and the bias resistors RG1B, RG2B, RG3B, RSD1B, RSD2B, and RSD3B, the added bottom body connection regions 210B and the associated bottom body HB vias 212BB may occupy a negligibly small footprint. Moreover, the area optionally occupied by the bottom local body bias circuits LB1B, LB2B, and LB3B is now released (if the bottom local body bias circuits LBxB are formed external to or partially overlapping the corresponding bottom active switch region 206Bx). As such, to achieve a same device width W1B for each bottom active switch region 206B, the bottom wafer 242B may have substantially the same wafer width WW2 as the bottom wafer 222B.

The top wafer 242T illustrated in FIG. 13B is substantially similar to the top wafer 222T illustrated in FIG. 6B, with the exception that the top body connection regions 210T (e.g., a first top body connection region 210T1, a second top body connection region 210T2, and a third top body connection region 210T3) and their associated top body HB vias 212TB used for body interconnects between the top FETs QxT and the bottom FETs QxB are added. Herein, since the top wafer 242T does not include any bias resistors, when each top active switch region 206T still has a width W1T the same as the width W1B of the bottom active switch region 206B in the bottom wafer 242B, the top wafer 242T, with the wafer width WW2, will have sufficient spare space to accommodate the top body connection regions 210T and their associated top body HB vias 212TB. As such, the top and bottom wafers 242T and 242B can also provide the same total device width Wtotal1=W1B+W1T as that of the top wafer 222T and the bottom wafer 222B with substantially the same footprint/wafer width WW2.

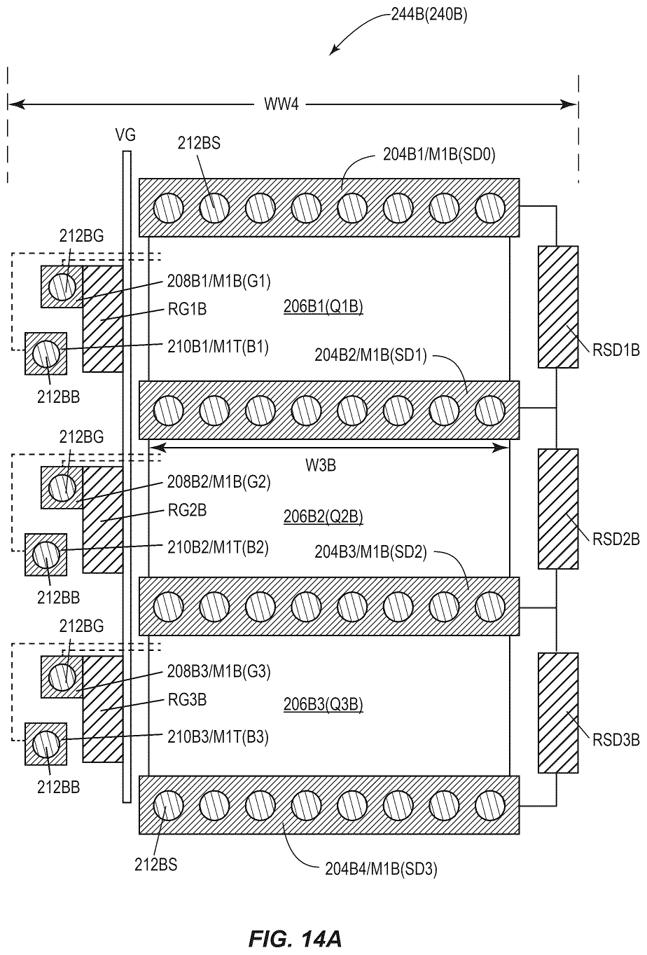

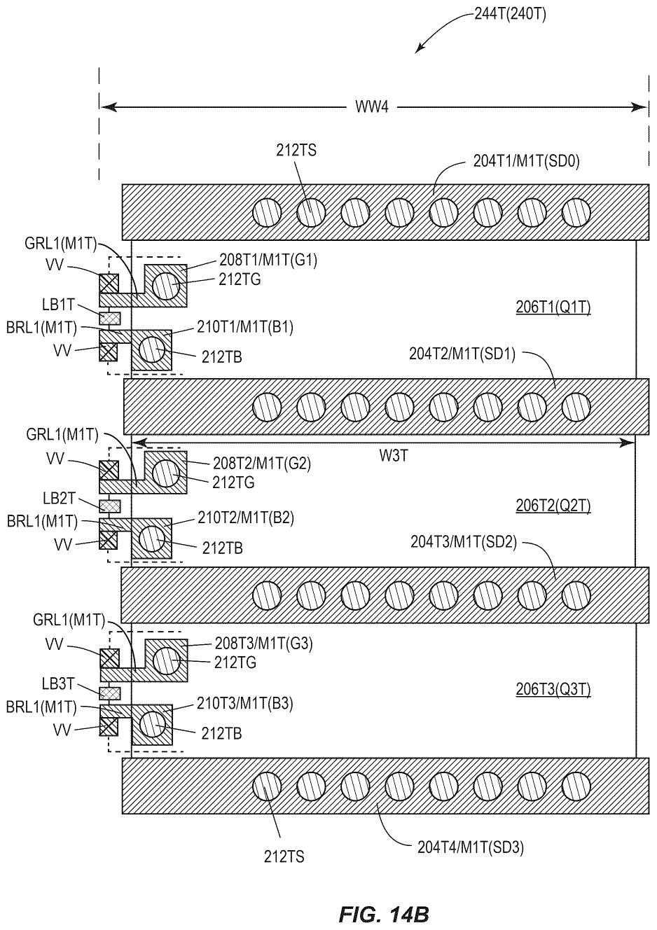

FIGS. 14A and 14B illustrate an improved implementation 244 of the RF switch structure 240 according to some embodiments of the present disclosure. FIG. 14A illustrates a top perspective view of a layout of a bottom wafer 244B, within which the bottom switch portion 240B is implemented, and FIG. 14B illustrates a bottom perspective view of a layout of a top wafer 244T, within which the top switch portion 240T is implemented. The top wafer 244T is bonded to and placed over the bottom wafer 244B, such that the set of the top FETs QxT in the top wafer 244T are opposite to the set of the bottom FETs QxB in the bottom wafer 244B, respectively. Each of the bottom wafer 244B and the top wafer 244T may include multiple metal layers and different vertical vias VV between the metal layers to achieve electrical connections (e.g., similar to the illustration shown in FIG. 3C, the first bottom metal layer M1B, the second bottom metal layer M2B, the third bottom metal layer M3B, the first top metal layer M1T, the second top metal layer M2T, and the third top metal layer M3T).

Herein, the bottom wafer 244B shown in FIG. 14A has a similar layout and configuration as the bottom wafer 242B shown in FIG. 13A, while FET device size reduction can be achieved in the bottom wafer 244B (more details are in the following description). The top wafer 244T shown in FIG. 14B has a similar layout and configuration to the top wafer 242T shown in FIG. 13B, but with improved space utilization. Within the top wafer 244T, each top active switch region 206T extends along the direction of a device width (e.g., along the device width W3T) to at least partially cover the areas of the gate and source-drain bias resistors RG1B, RG2B, RG3B, RSD1B, RSD2B, and RSD3B that surround the corresponding bottom active switch region 206B within the bottom wafer 244B. In addition, each top active switch region 206T may extend further (along the direction of the device width) and horizontally overlap with its corresponding top gate connection region 208T (i.e., each top gate connection region 208T is horizontally confined in a corresponding top active switch region 206T) and corresponding top body connection region 210T (i.e., each top body connection region 210T is horizontally confined in the corresponding top active switch region 206T). As such, the device width W3T of each top active switch region 206T is larger than the device width W3B of the corresponding bottom active switch region 206B. Depending on different implementations, each top local body bias circuit LBxT may be formed external to, fully contained within, or partially overlapping the corresponding bottom active switch region 206Tx.

In some applications, each top active switch region 206T extends along the direction of the device width to at least partially cover the areas of the gate and source-drain bias resistors RG1B, RG2B, RG3B, RSD1B, RSD2B, and RSD3B that surround the corresponding bottom active switch region 206B within the bottom wafer 244B, but without overlapping with its corresponding top gate connection region 208T or top body connection region 210T (not shown). Still, each top active switch region 206T has a larger device width than that of the corresponding bottom active switch region 206B.

If each top active switch region 206T overlaps its corresponding top gate connection region / 8T/ top body connection region 210T, extra route lines may be needed for electrical connections within the top wafer 244T. As described above (for the top wafer 226T), to electrically connect each top gate connection region 208T to a gate Gx of a corresponding top FET QxT (within the corresponding top active switch region 206T) without shorting circuits, the top wafer 244T may include multiple first gate route lines GRL1 formed from the first top metal layer M1T to provide an electrical connection from the top gate connection region 208T towards a location horizontally outside of the corresponding top active switch region 206T. In addition, the top wafer 244T also includes other gate route lines formed from the second top metal layer M2T and the third top metal layer M3T (located higher than the first top metal layer M1T) and multiple vertical vias VV (e.g., vertical vias between the first gate route lines GRL1 and the other gate route lines, vertical vias between the other gate route lines, and vertical vias between the other gate route lines and the gate Gx) to connect each top gate connection region 208T to the gate Gx within the corresponding top active switch region 206T.

Similarly, to electrically connect each top body connection region 210T to a body Bx of a corresponding top FET QxT (within the corresponding top active switch region 206T) without shorting circuits, the top wafer 244T may include multiple first body route lines BRL1 formed from the first top metal layer M1T to provide an electrical connection from the top body connection region 210T towards a location horizontally outside of the corresponding top active switch region 206T. In addition, the top wafer 244T also includes other body route lines formed from the second top metal layer M2T and the third top metal layer M3T (located higher than the first top metal layer M1T) and multiple vertical vias VV (e.g., vertical vias between the first body route lines BRL1 and the other body route lines, vertical vias between the other body route lines, and vertical vias between the other body route lines and the body Bx) to connect each top body connection region 210T to the body Bx within the corresponding top active switch region 210T. Herein, extra usage of the first top metal layer M1T (e.g., the first gate route lines GRL1, the first body route lines BRL1, and the extended width of the top source/drain regions 204T) may help the top HB vias 212T to dissipate heat generated in the top wafer 244T.

In this illustration, each top FET QxT with the device width W3T in the top wafer 244T is electrically parallel to a corresponding bottom FET QxB with the device width W1B in the bottom wafer 244B. A total device width of the FETs in both the top and bottom wafers 244T and 244B will be Wtotal3=W1B+W3T (where W3T>W1B). If the device width W3B of the bottom FETs QxB in the bottom wafer 244B is equal to the device width W1B of the bottom FETs QxB in the bottom wafer 222B, the bottom wafer 244B may have a wafer width WW4 that is substantially the same as the wafer width WW2 of the bottom wafer 222B. On the other hand, the top wafer 244T, having a wafer width WW4 equal to the wafer width WW2 of the top wafer 222T, will have the device width W3T for the top FETs QxT that is greater than the device width W1T of the top FETs QxT in the top wafer 222T. Therefore, with the same footprint/wafer width (WW2=WW4), the total device width Wtotal3 of the FETs in both the top and bottom wafers 244T and 244B will be larger than the total device width Wtotal1 of the FETs in both the top and bottom wafers 242T and 242B (FIGS. 13A and 13B). The increased total device width Wtotal3 of the FETs in both top and bottom wafers 244T and 244B may further enhance the overall electrical performance (e.g., reduced turn-on resistance) of the RF switch structure 240.

Alternatively, to maintain the same overall electrical performance (e.g., maintain the same turn-on resistance, where Wtotal3=Wtotal1), the footprint/wafer width WW4 of the implementation 244 can be smaller than the footprint/wafer width WW2 of the implementation 242. In a non-limiting example, to achieve the same total device width (Wtotal3=Wtotal1), the device width W3B of the bottom wafer 244B may be reduced by approximately 14% compared to the device width W1B of the bottom wafer 242B, while the device width W3T of the bottom wafer 244T may be increased by approximately 14% compared to the device width W1T of the top wafer 242T. When the gate and source-drain resistors RG1B, RG2B, RG3B, RSD1B, RSD2B, and RSD3B, and the top local body bias circuits LB1T, LB2T, and LB3T are factored in, the wafer width WW4 of the top/bottom wafer 244T/244B is about 90% of the wafer width WW2 of the top/bottom wafer 242T/242B. An area ratio between the bottom FETs QxB and the bias resistors (the gate and source-drain resistors RG1B, RG2B, RG3B, RSD1B, RSD2B, and RSD3B) will determine the total area/footprint reduction for the implementation 244. The higher that area ratio is, the larger the potential total area/footprint shrink is.

The RF switch structure 220, 230, or 240, which employs the local body bias circuitry in the bottom switch portion and/or the top switch portion, achieves the gate DC voltage biasing through a same resistor configuration of RG1B, RG2B, and RG3B. Specifically, within the RF switch structure 220, 230, or 240, each gate bias resistor RGxB is coupled between the gate voltage terminal VG and the gate terminal Gx of the corresponding bottom FET QxB, and each gate bias resistor RGxB may have a same resistance. The gate voltage signal present at the gate voltage terminal VG may be provided by a gate voltage source through a large resistor (not shown), thereby establishing a high impedance at the gate voltage terminal VG. In different applications, gate DC voltage biasing of an RF switch structure can be achieved through various resistor configurations, within which resistors may have different electrical connections and may have the same or different resistances.

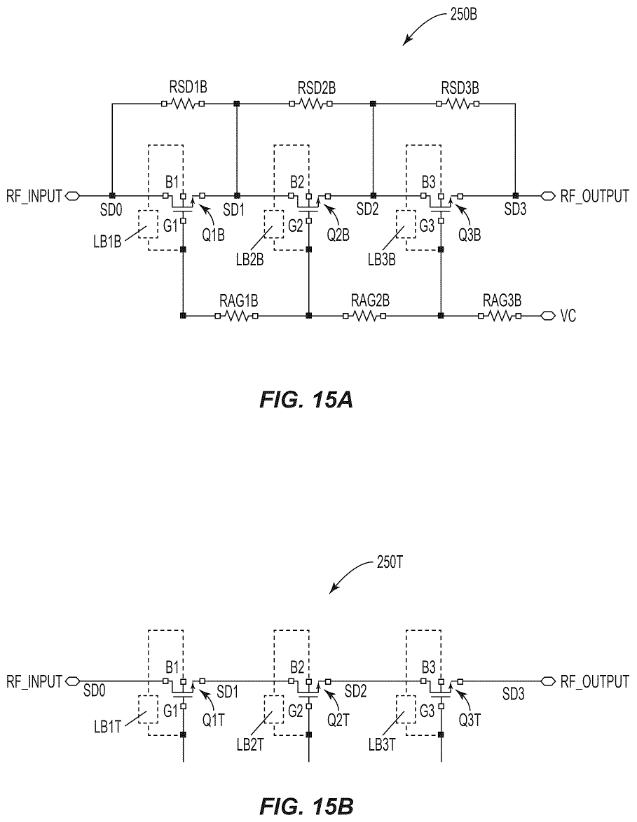

FIGS. 15A and 15B illustrate schematics of an exemplary RF switch structure 250 having a stacked configuration and employing local body bias circuitry according to some embodiments of the present disclosure. Herein, FIG. 15A shows a schematic of a bottom switch portion 250B of the RF switch structure 250 intended to be implemented in a bottom wafer, while FIG. 15B shows a schematic of a top switch portion 250T of the RF switch structure 250 intended to be implemented in a top wafer. At least one of the bottom switch portion 250B and the top switch portion 250T utilizes the local body bias circuits LBxB/LBxT to achieve local body DC voltage biasing.

The bottom switch portion 250B illustrated in FIG. 15A is substantially similar to the bottom switch portion 220B illustrated in FIG. 4A, except for the gate DC voltage bias configuration. Additionally, the bottom local body bias circuits LBxB might be omitted in the bottom switch portion 250B (if the top local body bias circuits LBxT are presented in the top switch portion 250T). In this illustration, two alternative gate bias resistors (e.g., a first alternative gate bias resistor RAG1B and a second alternative gate bias resistor RAG2B) are coupled in series between the gate terminal G1 of the first bottom FET Q1B and the gate terminal G3 of the third bottom FET Q3B, while the gate terminal G2 of the second bottom FET Q2B is coupled to a joint node of the first alternative gate bias resistor RAG1B and the second alternative gate bias resistor RAG2B. Additionally, a common gate bias resistor RGCB is coupled between the gate voltage terminal VG and the gate terminal G3 of the third bottom FET Q3B. In different applications, the common gate bias resistor RGCB might be is coupled between the gate voltage terminal VG and the gate terminal of another bottom FET QxB (e.g., the gate terminal of the first or second bottom FET Q1B or Q2B, not shown). The first alternative gate bias resistor RAG1B, the second alternative gate bias resistor RAG2B, and the common gate bias resistor RGCB might have any resistance values depending on different applications. In one embodiment, the first alternative gate bias resistor RAG1B, the second alternative gate bias resistor RAG2B, and the common gate bias resistor RGCB might have a same resistance value.

The top switch portion 250T illustrated FIG. 15B is substantially similar to the top switch portion 220T illustrated in FIG. 4B, and optionally, the top local body bias circuits LBxT might be omitted in the top switch portion 250T (if the bottom local body bias circuits LBxB are presented in the bottom switch portion 250B). In different applications, the top switch portion 250T may include fewer or more top FETs coupled in series between the RF_INPUT terminal and the RF_OUTPUT terminal, and optionally fewer or more corresponding top local body bias circuits LBxT. The bottom switch portion 250B correspondingly may include fewer or more bottom FETs coupled in series between the RF_INPUT terminal and the RF_OUTPUT terminal, fewer or more corresponding source-drain bias resistors RSDxB, fewer or more corresponding alternative gate bias resistors RAGxB, and optionally fewer or more corresponding bottom local body bias circuits LBxB.

Herein, when there are N (N is an integer number>=2) bottom FETs coupled in series between the RF_INPUT terminal and the RF_OUTPUT terminal, there will be N-1 alternative gate bias resistors coupled in series between a gate of an end bottom FET (e.g., the first bottom FET Q1B) and a gate of the other end bottom FET (e.g., the third bottom FET Q3B). A gate of each remaining bottom FET is coupled to a corresponding joint node of two adjacent ones of the alternative gate bias resistors (e.g., the gate of the second bottom FET Q2B is coupled to a joint node of the first and second alternative gate bias resistors RAG1B and RAG2B). Additionally, the common gate bias resistor RGCB is coupled between the gate voltage terminal VG and the gate of one of the N bottom FETs (e.g., the gate of any of the first, second, and third bottom FETs Q1B, Q2B, and Q3B). The gate voltage signal present at the gate voltage terminal VG may be provided by a gate voltage source through a large resistor (not shown), thereby establishing a high impedance at the gate voltage terminal VG. Each top FET and its corresponding bottom FET may still be connected and parallel to each other, and utilize the same DC voltage bias configurations (i.e, the same alternative gate bias resistors, common gate bias resistor, and source-drain bias resistors) implemented in the bottom wafer. The RF switch structure 250 may be implemented in a configuration similar to that shown in one of FIGS. 6A-6C, 7A-7B, 8A-8C, 10A-10B, 11A-11B, 13A-13B, or 14A-14B. For instance, the gate bias resistors RGxB in the RF switch structure 250 may be implemented at similar locations/areas as described above, but with different connection routing.

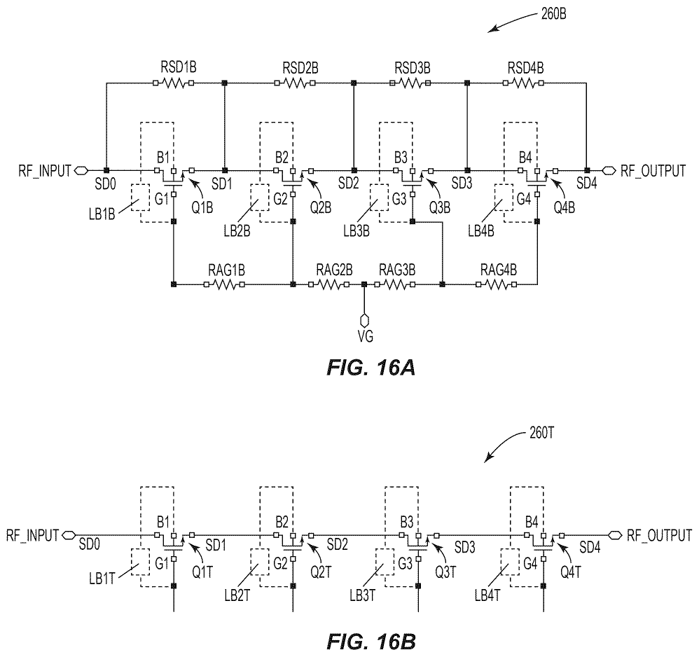

FIGS. 16A and 16B illustrate schematics of an exemplary RF switch structure 260 having a stacked configuration and employing local body bias circuitry according to some embodiments of the present disclosure. Herein, FIG. 16A shows a schematic of a bottom switch portion 260B of the RF switch structure 260 intended to be implemented in a bottom wafer, while FIG. 16B shows a schematic of a top switch portion 260T of the RF switch structure 260 intended to be implemented in a top wafer. At least one of the bottom switch portion 260B and the top switch portion 260T utilizes the local body bias circuits LBxB/LBxT to achieve local body DC voltage biasing.

The bottom switch portion 260B illustrated in FIG. 16A is substantially similar to the bottom switch portion 220B illustrated in FIG. 4A, except for the gate DC voltage bias configuration and the addition of a fourth bottom FET Q4B along with its associated fourth source-drain bias resistor RSD4B and an optional fourth bottom local body bias circuit LB4B. Herein, the fourth bottom FET Q4B is connected after the third bottom FET Q3B and before the RF_OUTPUT terminal, and the fourth source-drain bias resistor RSD4B is connected between a source and a drain of the fourth bottom FET Q4B. Accordingly, the node SD3, which is connected to the source of the third bottom FET Q3B, no longer serves as the output node coupled to the RF_OUTPUT terminal, but instead is a joint node between the source of the third bottom FET Q3B and the drain of the fourth bottom FET Q4B. Herein, a node SD4 connected to the source of the fourth bottom FET Q4B serves as the output node, which is coupled to the RF_OUTPUT terminal.

In this illustration, the first and second alternative gate bias resistors RAG1B and RAG2B are coupled in series between the gate voltage terminal VG and a gate terminal G1 of the first bottom FET Q1B, while third and fourth alternative gate bias resistors RAG3B and RAG4B are coupled in series between the gate voltage terminal VG and the gate terminal G4 of the fourth bottom FET Q4B. Additionally, the gate terminal G2 of the second bottom FET Q2B is coupled to a joint node of the first alternative gate bias resistor RAG1B and the second alternative gate bias resistor RAG2B, and the gate terminal G3 of the third bottom FET Q3B is coupled to a joint node of the third alternative gate bias resistor RAG3B and the fourth alternative gate bias resistor RAG4B. Each alternative gate bias resistor RAGxB might have any resistance values depending on different applications. In one embodiment, each alternative gate bias resistor RAGxB might have a same resistance value. In another embodiment, the two alternative gate bias resistors directly connected to the gate voltage terminal VG (e.g., the second and third gate bias resistors RAG2B or RAG3B) each has a resistance equal to half the resistance of each of the remaining gate bias resistors (e.g., the first or fourth gate bias resistors RAG1B or RAG4B). Optionally, the bottom local body bias circuits LBxB might be omitted in the bottom switch portion 260B (if the top local body bias circuits LBxT are presented in the top switch portion 260T).

The top switch portion 260T illustrated FIG. 16B is substantially similar to the top switch portion 220T illustrated in FIG. 4B, with the exception that the top switch portion 260T further includes a fourth top FET Q4T connected after the third top FET Q3T and before the RF_OUTPUT terminal, and optionally, a fourth top local body bias circuit LB4T. The top local body bias circuits LBxT might be omitted in the top switch portion 260T, if the bottom local body bias circuits LBxB are presented in the bottom switch portion 260B. In different applications, the top switch portion 260T may include fewer or more number of top FETs coupled in series between the RF_INPUT terminal and the RF_OUTPUT terminal, and optionally fewer or more corresponding top local body bias circuits LBxT. Correspondingly, the bottom switch portion 260B may include fewer or more number of bottom FETs also coupled in series between the RF_INPUT and RF_OUTPUT terminals, fewer or more corresponding source-drain bias resistors RSDxB, fewer or more corresponding alternative gate bias resistors RAGxB, and optionally fewer or more corresponding bottom local body bias circuits LBxB.

In the case where the number of bottom FETs QxB and associated alternative gate bias resistors is N+M (e.g., where N and M are each arbitrary integers, and N and M might be the same or different), N alternative gate bias resistors are coupled in series between the gate voltage terminal VG and a gate of one end bottom FET (e.g., the first and second alternative gate bias resistors RAG1B and RAG2B are coupled in series between the gate voltage terminal VG and a gate of the end bottom FET Q1B), and other M alternative gate bias resistors are coupled in series between the gate voltage terminal VG and a gate of another end bottom FET (e.g., the third and fourth alternative gate bias resistors RAG3B and RAG4B are coupled in series between the gate voltage terminal VG and the gate of the other end bottom FET Q4B). The gate of each remaining bottom FET (if it exists) is coupled to a corresponding joint node of two adjacent ones of the N alternative gate bias resistors (e.g., the gate of the second bottom FET Q2B is coupled to a joint node of the first and second alternative gate bias resistors RAG1B and RAG2B) or coupled to a corresponding joint node of two adjacent ones of the M alternative gate bias resistors (e.g., the gate of the third bottom FET Q3B is coupled to a joint node of the third and fourth alternative gate bias resistors RAG3B and RAG4B). The gate voltage signal present at the gate voltage terminal VG may be provided by a gate voltage source through a large resistor (not shown), thereby establishing a high impedance at the gate voltage terminal VG. Each top FET and its corresponding bottom FET may still be connected and parallel to each other, and utilize the same DC voltage bias configurations (i.e., the same alternative gate bias resistors and source-drain bias resistors) implemented in the bottom wafer. The RF switch structure 260 may be implemented in a configuration similar to that shown in one of FIGS. 6A-6C, 7A-7B, 8A-8C, 10A-10B, 11A-11B, 13A-13B, or 14A-14B, where the gate bias resistors RGxB in the RF switch structure 260 may be implemented at similar locations/areas as described above, but with different connection routing.

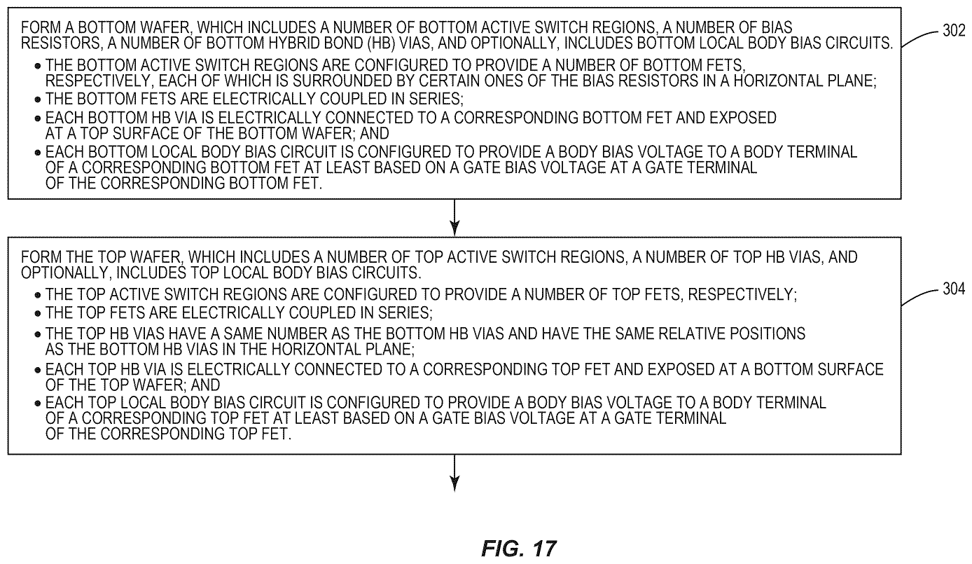

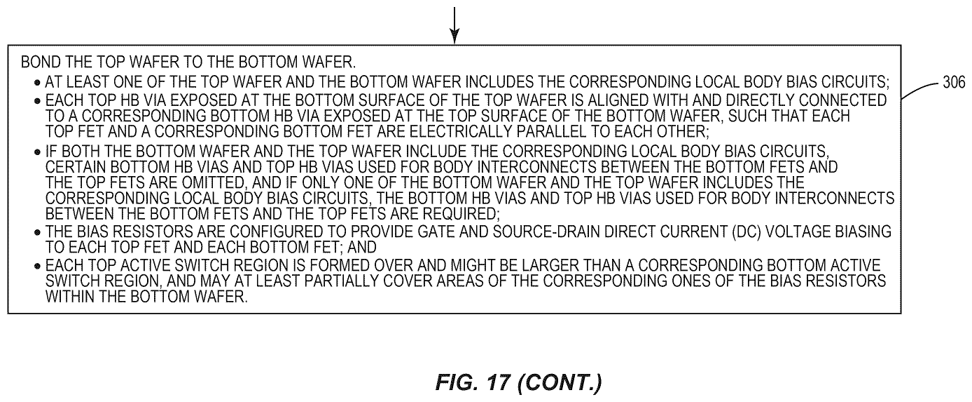

FIG. 17 illustrates a flowchart of an exemplary method of providing the implementations 222/224/226/232/234/242/244 shown in one of FIGS. 6A-6C, 7A-7B, 8A-8C, 10A-10B, 11A-11B, 13A-13B, or 14A-14B, according to some embodiments of the present disclosure. Although the process steps are illustrated in a series, the process steps are not necessarily order dependent. Some steps may be taken in a different order than that presented. Further, processes within the scope of this disclosure may include fewer or more steps than those illustrated in FIG. 17.

Initially, a bottom wafer (e.g., the bottom wafer 222B/224B/226B/232B/234B/242B/244B) is formed (step 302), which includes a number of bottom active switch regions (e.g., the bottom active switch regions 206B), a number of bias resistors (e.g., the bottom gate, and source-drain resistors RG1B, RG2B, RG3B, RSD1B, RSD2B, and RSD3B), and a number of bottom HB vias (e.g., the bottom HB vias 212B). Herein, the bottom active switch regions are configured to provide a number of bottom FETs (e.g., the bottom FETs QxB), respectively, each of which is surrounded by certain ones of the bias resistors in a horizontal plane. The bottom FETs are electrically coupled in series. Each bottom HB via is electrically connected to a corresponding bottom FET and exposed at a top surface of the bottom wafer. The bottom wafer formed herein may further include bottom local body bias circuits (e.g., the bottom local body bias circuits LBxB) to achieve DC body biasing inside the bottom wafer without using any body bias resistor. Each bottom local body bias circuit is configured to provide a body bias voltage to a body terminal of a corresponding bottom FET at least based on a gate bias voltage at a gate terminal of the corresponding bottom FET.

In addition, a top wafer (e.g., the top wafer 222T/224T/226T/232T/234T/242T/244T) is also formed (step 304), which includes a number of top active switch regions (e.g., the top active switch regions 2064T), a number of top HB vias (e.g., the top HB vias 212T). Herein, the top active switch regions are configured to provide a number of top FETs (e.g., the top FETs QxT), respectively. The top FETs are electrically coupled in series. The top HB vias have a same number as the bottom HB vias and have the same relative positions as the bottom HB vias in the horizontal plane. Each top HB via is electrically connected to a corresponding top FET and exposed at a bottom surface of the top wafer. The top wafer formed herein may further include top local body bias circuits (e.g., the top local body bias circuits LBxT) to achieve DC body biasing inside the top wafer. Each top local body bias circuit is configured to provide a body bias voltage to a body terminal of a corresponding top FET at least based on a gate bias voltage at a gate terminal of the corresponding top FET.

Once the bottom wafer and the top wafer are formed, the top wafer is bonded to the bottom wafer (step 306). Herein, each top HB via exposed at the bottom surface of the top wafer is aligned with and directly connected to a corresponding bottom HB via exposed at the top surface of the bottom wafer, such that each top FET and a corresponding bottom FET are electrically parallel to each other. Note that at least one of the top wafer and the bottom wafer includes the corresponding local body bias circuits (e.g., the top local body bias circuits LBxT or the bottom local body bias circuits LBxB). If both the bottom wafer and the top wafer include the corresponding local body bias circuits, certain bottom HB vias and top HB vias used for body interconnects between the bottom FETs and the top FETs are omitted. If only one of the bottom wafer and the top wafer includes the corresponding local body bias circuits, the bottom HB vias and top HB vias used for body interconnects between the bottom FETs and the top FETs are required. The bias resistors are configured to provide the gate and source-drain DC voltage biasing to each top FET and each bottom FET. Each top active switch region is formed over and might be larger than a corresponding bottom active switch region, and may at least partially cover areas of the corresponding ones of the bias resistors within the bottom wafer.

According to aspects disclosed herein, at least one RF switch structure 220/230/240/250/260, which may be provided as the implementations 222/224/226/232/234/242/244 (shown in FIGS. 4A-16B), can be included in any processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

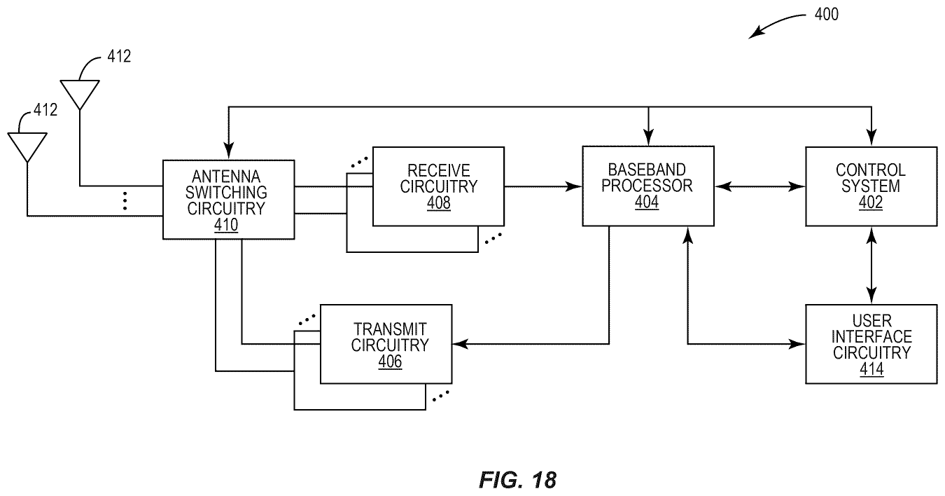

With reference to FIG. 18, the concepts described above may be implemented in various types of communication devices 400, such as those listed in the previous paragraph. The communication device 400 will generally include a control system 402, a baseband processor 404, transmit circuitry 406, receive circuitry 408, antenna switching circuitry 410, multiple antennas 412, and user interface circuitry 414. In a non-limiting example, the control system 402 can be a field-programmable gate array (FPGA) or an application-specific integrated circuit (ASIC). In this regard, the control system 402 can include at least a microprocessor(s), an embedded memory circuit(s), and a communication bus interface(s). The receive circuitry 408 receives radio frequency signals via the antennas 412 and through the antenna switching circuitry 410 from one or more base stations. A low noise amplifier and a filter of the receive circuitry 408 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 404 processes the digitized received signal to extract the information or data bits conveyed in the received signal. This processing typically comprises demodulation, decoding, and error correction operations, as will be discussed in greater detail below. The baseband processor 404 is generally implemented in one or more digital signal processors (DSPs) and ASICs.

For transmission, the baseband processor 404 receives digitized data, which may represent voice, data, or control information, from the control system 402, which it encodes for transmission. The encoded data is output to the transmit circuitry 406, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 412 through the antenna switching circuitry 410. The multiple antennas 412 and the replicated transmit and receive circuitries 406, 408 may provide spatial diversity. Modulation and processing details will be understood by those skilled in the art. In some embodiments, the at least one RF switch structure 220/230/240/250/260, which may be provided as the implementations 222/224/226/232/234/242/244 (shown in FIGS. 4A-16B), can be provided in any one or more of the circuitries in the communication device 400, such as the antenna switching circuitry 410.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A radio frequency (RF) switch structure comprising:
a bottom wafer including a plurality of bottom active switch regions, a plurality of bias resistors, and a plurality of bottom hybrid bond (HB) vias, wherein:
the plurality of bottom active switch regions is configured to provide bottom field-effect transistors (FETs), which are electrically coupled in series and surrounded by the plurality of bias resistors in a horizontal plane; and
each of the plurality of bottom HB vias is exposed at a top surface of the bottom wafer and electrically connected to a corresponding one of the bottom FETs; and
a top wafer bonded to and positioned over the bottom wafer and including a plurality of top active switch regions and a plurality of top HB vias, wherein:
the plurality of top active switch regions is formed over the plurality of bottom active switch regions, respectively, and configured to provide top FETs that are electrically coupled in series;
each of the plurality of top HB vias is exposed at a bottom surface of the top wafer, electrically connected to a corresponding one of the top FETs, and aligned with and directly connected to a corresponding one of the plurality of bottom HB vias, such that each of the top FETs is electrically parallel to a corresponding one of the bottom FETs;
the plurality of bias resistors is configured to provide gate and source-drain direct current (DC) voltage biasing to each of the top FETs and each of the bottom FETs; and
at least one of the top wafer and the bottom wafer further includes a plurality of local body bias circuits, which is configured to provide body DC voltage biasing to each of the top FETs and/or to each of the bottom FETs based on at least the gate DC voltage biasing.

2. The RF switch structure of claim 1 wherein:
the plurality of local body bias circuits includes a plurality of bottom local body bias circuits and a plurality of top local body bias circuits;
the bottom wafer includes the plurality of bottom local body bias circuits, which is configured to provide body DC voltage biasing to each of the bottom FETs based on at least the gate DC voltage biasing; and
the top wafer includes the plurality of top local body bias circuits, which is configured to provide body DC voltage biasing to each of the top FETs based on at least the gate DC voltage biasing.

3. The RF switch structure of claim 2 wherein:
the plurality of bottom local body bias circuits is positioned horizontally outside the plurality of bottom active switch regions; and
the plurality of top local body bias circuits is positioned horizontally outside the plurality of top active switch regions.

4. The RF switch structure of claim 2 wherein:
each of the plurality of bottom local body bias circuits is implemented by an integrated diode confined within a corresponding one of the plurality of bottom active switch regions; and
each of the plurality of top local body bias circuits is implemented by an integrated diode confined within a corresponding one of the plurality of top active switch regions.

5. The RF switch structure of claim 2 wherein each of the plurality of top active switch regions has a same device width as a corresponding one of the plurality of bottom active switch regions.

6. The RF switch structure of claim 2 wherein each of the plurality of top active switch regions has a greater device width than a corresponding one of the plurality of bottom active switch regions, and at least partially covers areas of the plurality of bias resistors within the bottom wafer.

7. The RF switch structure of claim 2 wherein:
the bottom wafer further includes a plurality of bottom source/drain connection regions and a plurality of bottom gate connection regions, wherein:
each of the plurality of bottom source/drain connection regions is connected to a drain or a source of a corresponding one of the bottom FETs, or connected to a drain and a source of two adjacent ones of the bottom FETs, while each of the plurality of bottom gate connection regions is connected to a gate of the corresponding one of the bottom FETs; and
each of the plurality of bottom active switch regions is located between two adjacent ones of the plurality of bottom source/drain connection regions in the horizontal plane;
the top wafer further includes a plurality of top source/drain connection regions and a plurality of top gate connection regions, wherein:
each of the plurality of top source/drain connection regions is connected to a drain or a source of a corresponding one of the top FETs, or connected to a drain and a source of two adjacent ones of the top FETs, while each of the plurality of top gate connection regions is connected to a gate of the corresponding one of the top FETs; and
each of the plurality of top active switch regions is located between two adjacent ones of the plurality of top source/drain connection regions in the horizontal plane;
each of the plurality of bottom HB vias is confined within a corresponding one of the plurality of bottom source/drain connection regions or a corresponding one of the plurality of bottom gate connection regions, and is electrically connected to a source/drain of the corresponding one of the bottom FETs through the corresponding one of the plurality of bottom source/drain connection regions or electrically connected to a gate of the corresponding one of the bottom FETs through the corresponding one of the plurality of bottom gate connection regions;
each of the plurality of top HB vias is confined within a corresponding one of the plurality of top source/drain connection regions or a corresponding one of the plurality of top gate connection regions, and is electrically connected to a source/drain of the corresponding one of the top FETs through the corresponding one of the plurality of top source/drain connection regions or electrically connected to a gate of the corresponding one of the top FETs through the corresponding one of the plurality of top gate connection regions; and
none of the plurality of bottom HB vias and the plurality of top HB vias are configured to electrically connect bodies of the bottom FETs with bodies of the top FETs.

8. The RF switch structure of claim 7 wherein:
the plurality of bottom source/drain connection regions and the plurality of bottom gate connection regions are formed from a same first bottom metal layer, which is at a higher vertical level than the plurality of bottom active switch regions; and
the plurality of top source/drain connection regions and the plurality of top gate connection regions are formed from a same first top metal layer, which is at a lower vertical level than the plurality of top active switch regions.

9. The RF switch structure of claim 8 wherein:
each of the plurality of bottom gate connection regions is horizontally outside a corresponding one of the plurality of bottom active switch regions; and
each of the plurality of top gate connection regions is horizontally outside a corresponding one of the plurality of top active switch regions.

10. The RF switch structure of claim 8 wherein:
each of the plurality of bottom gate connection regions is horizontally outside a corresponding one of the plurality of bottom active switch regions; and
each of the plurality of top gate connection regions is horizontally confined in a corresponding one of the plurality of top active switch regions.

11. The RF switch structure of claim 1 wherein the body DC voltage biasing provided by the plurality of local body bias circuits is solely based on the gate DC voltage biasing.

12. The RF switch structure of claim 1 wherein the body DC voltage biasing provided by the plurality of local body bias circuits is partially based on the gate DC voltage biasing.

13. The RF switch structure of claim 1 wherein:
the plurality of bias resistors is placed around the plurality of bottom active switch regions along a device width direction; and
each of the plurality of top active switch regions is positioned over a corresponding one of the plurality of bottom active switch regions and extends in the device width direction to at least partially cover the areas of the plurality of bias resistors within the bottom wafer, such that each of the plurality of top active switch regions has a greater device width than the corresponding one of the plurality of bottom active switch regions.

14. The RF switch structure of claim 1 wherein:
the plurality of bias resistors includes a plurality of source-drain bias resistors and a plurality of gate bias resistors; and
each of the plurality of source-drain bias resistors is electrically coupled between a drain and a source of a corresponding one of the bottom FETs.

15. The RF switch structure of claim 14 wherein each of the plurality of gate bias resistors is coupled between a gate of a corresponding one of the bottom FETs and a gate terminal that provides a gate voltage signal.

16. The RF switch structure of claim 14 wherein:
the bottom FETs include N bottom FETs, wherein N is an integer equal to or greater than 2, and the N bottom FETs are coupled in series;
the plurality of gate bias resistors includes N-1 gate bias resistors that are coupled in series between gates of two end FETs of the N bottom FETs, and a common gate bias resistor that is coupled between a gate of one of the N bottom FETs and a gate voltage terminal that provides a gate voltage signal; and
a gate of each remaining one of the N bottom FETs other than the two end FETs is coupled to a corresponding joint node of two adjacent ones of the N-1 gate bias resistors.

17. The RF switch structure of claim 16 wherein the common gate bias resistor is coupled between a gate of one end FET of the N bottom FETs and the gate voltage terminal.

18. The RF switch structure of claim 16 wherein the common gate bias resistor is coupled between the gate voltage terminal and a gate of one of the N bottom FETs other than the two end FETs.

19. The RF switch structure of claim 14 wherein:
the bottom FETs include N+M bottom FETs, wherein each of N and M is an integer, and the N+M bottom FETs are coupled in series;
the plurality of gate bias resistors includes N+M gate bias resistors;
N gate bias resistors are coupled in series between a gate of one end bottom FET of the N+M bottom FETs and a gate voltage terminal that provides a gate voltage signal, while M gate bias resistors are coupled in series between a gate of another end bottom FET of the M+N bottom FETs and the gate voltage terminal; and
a gate of each remaining one of the N bottom FETs other than the two end FETs is coupled to a corresponding joint node of two adjacent ones of the N gate bias resistors or a corresponding joint node of two adjacent ones of the M gate bias resistors.

20. The RF switch structure of claim 19 wherein N is equal to M.

21. The RF switch structure of claim 19 wherein N is different from M.

22. A communication device comprising:
receive circuitry;
transmit circuitry; and
antenna switching circuitry, which is configured to transmit radio frequency signals between antennas and the receive circuitry and/or between the antennas and the transmit circuitry, wherein at least the antenna switching circuitry includes an RF switch structure comprising:
a bottom wafer including a plurality of bottom active switch regions, a plurality of bias resistors, and a plurality of bottom hybrid bond (HB) vias, wherein:
the plurality of bottom active switch regions is configured to provide bottom field-effect transistors (FETs), which are electrically coupled in series and surrounded by the plurality of bias resistors in a horizontal plane; and
each of the plurality of bottom HB vias is exposed at a top surface of the bottom wafer and electrically connected to a corresponding one of the bottom FETs; and
a top wafer bonded to and positioned over the bottom wafer and including a plurality of top active switch regions and a plurality of top HB vias, wherein:
the plurality of top active switch regions is formed over the plurality of bottom active switch regions, respectively, and configured to provide top FETs that are electrically coupled in series;
each of the plurality of top HB vias is exposed at a bottom surface of the top wafer, electrically connected to a corresponding one of the top FETs, and aligned with and directly connected to a corresponding one of the plurality of bottom HB vias, such that each of the top FETs is electrically parallel to a corresponding one of the bottom FETs;
the plurality of bias resistors is configured to provide gate and source-drain direct current (DC) voltage biasing to each of the top FETs and each of the bottom FETs; and
at least one of the top wafer and the bottom wafer further includes a plurality of local body bias circuits, which is configured to provide body DC voltage biasing to each of the top FETs and/or to each of the bottom FETs based on at least the gate DC voltage biasing.

23. A method of implementing a radio frequency (RF) switch structure comprising:
forming a bottom wafer that includes a plurality of bottom active switch regions, a plurality of bias resistors, and a plurality of bottom hybrid bond (HB) vias, wherein:
the plurality of bottom active switch regions is configured to provide bottom field-effect transistors (FETs), which are electrically coupled in series and surrounded by the plurality of bias resistors in a horizontal plane; and
each of the plurality of bottom HB vias is exposed at a top surface of the bottom wafer and electrically connected to a corresponding one of the bottom FETs;
forming a top wafer that includes a plurality of top active switch regions and a plurality of top HB vias, wherein:
the plurality of top active switch regions is configured to provide top FETs that are electrically coupled in series;
each of the plurality of top HB vias is exposed at a bottom surface of the top wafer and electrically connected to a corresponding one of the top FETs; and
at least one of the top wafer and the bottom wafer further includes a plurality of local body bias circuits; and
bonding the top wafer to the bottom wafer, wherein:
each of the plurality of top HB vias is exposed at the bottom surface of the top wafer is aligned with and directly connected to a corresponding one of the plurality of bottom HB vias exposed at the top surface of the bottom wafer, such that each of the top FETs is electrically parallel to a corresponding one of the bottom FETs;
the plurality of bias resistors is configured to provide gate and source-drain direct current (DC) voltage biasing to each of the top FETs and each of the bottom FETs; and
the plurality of local body bias circuits is configured to provide body DC voltage biasing to each of the top FETs and/or to each of the bottom FETs based on at least the gate DC voltage biasing.
